(19) United States
(12) Patent Application Publication
(10) Pub. No.: US 2026/0215289 A1
(43) Pub. Date: Jul. 23, 2026

(54) SEMICONDUCTOR DEVICE, METHOD OF MANUFACTURING SEMICONDUCTOR DEVICE, SEMICONDUCTOR INSPECTION APPARATUS, AND SEMICONDUCTOR DEVICE INSPECTION JIG

(71) Applicant: Mitsubishi Electric Corporation, Tokyo (JP)

(72) Inventor: Tetsuya MIYATA, Tokyo (JP)

(73) Assignee: Mitsubishi Electric Corporation, Tokyo (JP)

(21) Appl. No.: 19/418,837

(22) Filed: Dec. 12, 2025

(30) Foreign Application Priority Data
Jan. 22, 2025 (JP) 2025-008938

(51) Int. Cl. H10W 46/00; H10P 72/00; H10W 74/10; H10W 90/00

(52) U.S. Cl. CPC H10W 46/401; H10P 72/0606; H10P 72/0618; H10W 46/103; H10W 46/607; H10W 74/114; H10W 90/754

(57) ABSTRACT

A semiconductor device according to the present disclosure has a structure in which terminals having different shapes coexist in one package or a structure in which distances between terminals exposed to outside of the package are not uniform in a portion in the package, the semiconductor device including: a semiconductor element; a resin portion that is provided to cover the semiconductor element; a plurality of terminals each having one end electrically connected to the semiconductor element and another end having an exposed portion exposed through a surface of the resin portion; and an identification portion that is provided on the surface of the resin portion, and has a function with which the position of the exposed portion of each of the plurality of terminals can be identified.

### BACKGROUND

### Technical Field

The present disclosure relates to a semiconductor device, a method of manufacturing semiconductor devices, a semiconductor inspection apparatus, and a semiconductor device inspection jig.

### Description of the Background Art

Semiconductor packages include discrete semiconductors and module semiconductors. A discrete semiconductor has about one or two semiconductor elements connected to a wiring member, and is housed in one package. Since there is a standard specification for discrete semiconductors, the package structure is the same for each type. Therefore, the manner of drawing terminals out of the package is the same for each type. Accordingly, among discrete semiconductors, terminals having the same shape normally exist in one package, and the distances between the terminals drawn out of the package are uniform in the one package.

On the other hand, a module semiconductor is formed with a plurality of combined discrete semiconductors housed in one package, and a plurality of semiconductor elements are connected to each other by a wiring member and are housed in the one package. Note that, to form a circuit by connecting a plurality of semiconductor elements housed in a package to an external power supply or a control apparatus, one end of each terminal, which is a wiring member, is drawn out of the package. Semiconductor modules are used in various applications such as in-vehicle applications, industrial applications, and consumer applications, and the package structure or the circuit configuration varies with each application. Therefore, how the terminals are drawn out of the outside of the package varies depending on the package structure or the circuit configuration. Depending on how the terminals are drawn out, there might be a case where terminals having different shapes coexist in one package, or a case where one package includes a portion in which the distances between the other ends of the terminals drawn out of the package are not uniform.

Further, semiconductor package inspection is performed in the post-process of the semiconductor manufacturing. In the semiconductor package inspection, electrical characteristic inspection for inspecting the presence or absence of a defect in electrical characteristics is performed. In the electrical characteristic inspection, a probe is brought into contact with a terminal drawn out of a semiconductor package, and electrical current is applied from the probe to the terminal, to evaluate the electrical characteristics of the semiconductor package.

As a method of bringing an inspection jig into contact with a terminal of a semiconductor package, there is a method of using an inspection apparatus called a flying probe tester, for example. In the flying probe tester, a probe is attached to a robot arm, and the robot arm is controlled by designating coordinates of the respective terminals of a semiconductor package beforehand, so that the probe can be moved to the position of each terminal.

Note that, in a discrete semiconductor, a mark called an index mark might be provided at the position corresponding to a terminal drawn out onto the surface of the package, to indicate the directionality of the package (a “semiconductor package” disclosed in Japanese Patent Application Laid-Open No. 2003-197848, for example). Among discrete semiconductors, the manner of drawing terminals out of the package is the same for one type as described above. Accordingly, the inspection apparatus can recognize the relative position of each terminal by recognizing the position of the index mark, and thus, can accurately move the probe to the position of each terminal.

In the invention disclosed in Japanese Patent Application Laid-Open No. 2003-197848, the index mark is provided at the position corresponding to a terminal. However, as described above, depending on how the terminals are drawn out, a semiconductor device might have a structure in which terminals of different shapes coexist in one package, or a structure in which the distances between the terminals drawn out of the package are not uniform in a portion in the single package. In that case, there is a problem in that, even if the inspection apparatus recognizes the position of the index mark, the inspection apparatus cannot recognize the accurate relative position of each terminal, and therefore, is unable to accurately move a probe to the position of each terminal.

### SUMMARY

The present disclosure aims to provide a semiconductor device that enables an inspection apparatus to recognize the accurate position of each terminal and accurately move a probe to the position of each terminal.

A semiconductor device according to the present disclosure has a structure in which terminals having different shapes coexist in one package or a structure in which distances between terminals exposed to outside of the package are not uniform in a portion in the package, the semiconductor device including: a semiconductor element; a resin portion that is provided to cover the semiconductor element; a plurality of terminals each having one end electrically connected to the semiconductor element and another end having an exposed portion exposed through a surface of the resin portion; and an identification portion that is provided on the surface of the resin portion, and has a function with which a position of the exposed portion of each of the plurality of terminals can be identified.

An inspection apparatus can recognize the accurate position of each terminal, and accurately move a probe to the position of each terminal.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a schematic top view of a semiconductor device according to a first preferred embodiment;

FIG. 2 is a schematic cross-sectional view of the semiconductor device according to the first preferred embodiment, taken along line X-X defined in FIG. 1;

FIG. 3 is a schematic side view of the semiconductor device according to the first preferred embodiment;

FIG. 4 is a schematic top view of the semiconductor device according to the first preferred embodiment;

FIG. 5 is a configuration diagram illustrating an example of a basic configuration of a semiconductor inspection apparatus that inspects electrical characteristics of the semiconductor device according to the first preferred embodiment;

FIG. 6 is a schematic perspective view illustrating an example of a basic configuration of a semiconductor inspection apparatus that inspects electrical characteristics of the semiconductor device according to the first preferred embodiment;

FIG. 7 is a schematic side view illustrating an example of a basic configuration of a semiconductor inspection apparatus that inspects electrical characteristics of the semiconductor device according to the first preferred embodiment;

FIG. 8 is a flowchart illustrating an operation flow of a semiconductor inspection apparatus that inspects electrical characteristics of the semiconductor device according to the first preferred embodiment;

FIG. 9 is a configuration diagram illustrating a first specific example configuration of a semiconductor inspection apparatus that inspects electrical characteristics of the semiconductor device according to the first preferred embodiment;

FIG. 10 is a flowchart illustrating an operation flow of a semiconductor inspection apparatus that inspects electrical characteristics of the semiconductor device according to the first preferred embodiment and has the first example configuration;

FIG. 11 is a configuration diagram illustrating a second specific example configuration of a semiconductor inspection apparatus that inspects electrical characteristics of the semiconductor device according to the first preferred embodiment;

FIG. 12 is a diagram illustrating a first specific example of an abnormality in a terminal of the semiconductor device according to the first preferred embodiment;

FIG. 13 is an enlarged view of a region A shown in FIG. 12, illustrating the first specific example of an abnormality in a terminal of the semiconductor device according to the first preferred embodiment;

FIG. 14 is a diagram illustrating a second specific example of an abnormality in a terminal of the semiconductor device according to the first preferred embodiment;

FIG. 15 is an enlarged view of a region A shown in FIG. 14, illustrating the second specific example of an abnormality in a terminal of the semiconductor device according to the first preferred embodiment;

FIG. 16 is a flowchart illustrating an operation flow of a semiconductor inspection apparatus that inspects electrical characteristics of the semiconductor device according to the first preferred embodiment and has the second example configuration;

FIG. 17 is a configuration diagram illustrating a third example configuration of a semiconductor inspection apparatus that inspects electrical characteristics of the semiconductor device according to the first preferred embodiment;

FIG. 18 is a schematic side view illustrating the third example configuration of a semiconductor inspection apparatus that inspects electrical characteristics of the semiconductor device according to the first preferred embodiment;

FIG. 19 is a schematic top view of a semiconductor device according to a first modification of the first preferred embodiment;

FIG. 20 is a schematic cross-sectional view of the semiconductor device according to the first modification of the first preferred embodiment, taken along line X-X defined in FIG. 19;

FIG. 21 is a schematic top view of a semiconductor device according to a second modification of the first preferred embodiment;

FIG. 22 is a schematic top view of a semiconductor device according to a second preferred embodiment;

FIGS. 23A and 23B are schematic side views of the semiconductor device according to the second preferred embodiment;

FIG. 24 is a schematic top view illustrating an example configuration of a semiconductor inspection apparatus that inspects electrical characteristics of the semiconductor device according to the second preferred embodiment;

FIG. 25 is a schematic top view of a semiconductor device according to a third preferred embodiment;

FIG. 26 is a schematic side view of the semiconductor device according to the third preferred embodiment;

FIG. 27 is a schematic top view of the semiconductor device according to the third preferred embodiment;

FIG. 28 is a schematic side view illustrating a configuration of a semiconductor inspection apparatus that inspects electrical characteristics of the semiconductor device according to the third preferred embodiment;

FIG. 29 is a schematic top view of a semiconductor device according to a modification of the third preferred embodiment;

FIG. 30 is a schematic side view of the semiconductor device according to the modification of the third preferred embodiment; and

FIG. 31 is a schematic top view of the semiconductor device according to a modification of the third preferred embodiment.

### DESCRIPTION OF THE PREFERRED EMBODIMENTS

### Introduction

One side in a direction parallel to the thickness direction of a semiconductor device is referred to as the “upper” side, and the other side is referred to as the “lower” side. One of the two main surfaces of a substrate, a layer, or some other member is referred to as the upper surface, and the other surface is referred to as the lower surface. The “upper” and “lower” directions are not necessarily directions based on gravity or the directions at the time of mounting the semiconductor device. Also, the upper surface, the lower surface, and the side surfaces of a substrate, a layer, or some other member are referred to as surfaces.

Further, for ease of explanation, in the description below, the width direction of a semiconductor device is referred to as the X-axis direction, the depth direction of the semiconductor device intersecting the X-axis direction is referred to as the Y-axis direction, and the thickness direction or the depth direction of the semiconductor device, which is the normal direction with respect to the X-Y plane, is referred to as the Z-axis direction.

Also, the drawings are schematically illustrated, and mutual relationships between sizes and positions of images shown in different drawings are not necessarily accurately shown, and can be changed as appropriate. Furthermore, in the description below, the same components are denoted by the same reference signs, and names and functions thereof are also the same. Therefore, detailed explanation thereof will be omitted in some cases.

### First Preferred Embodiment

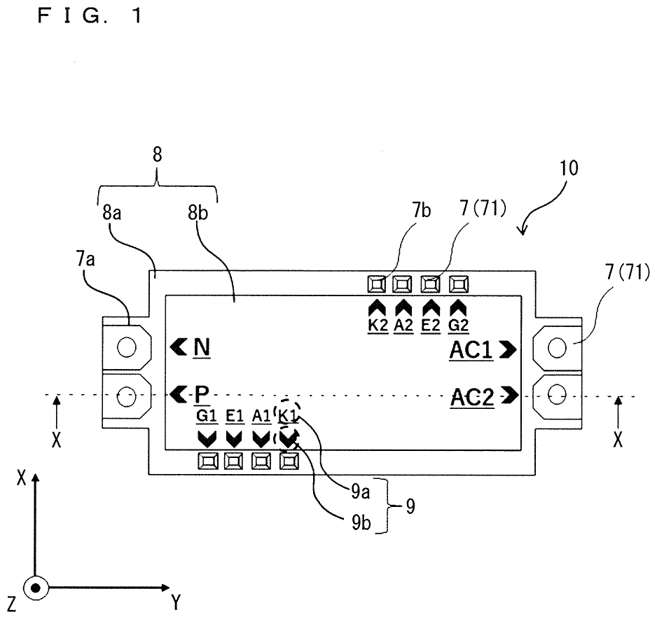

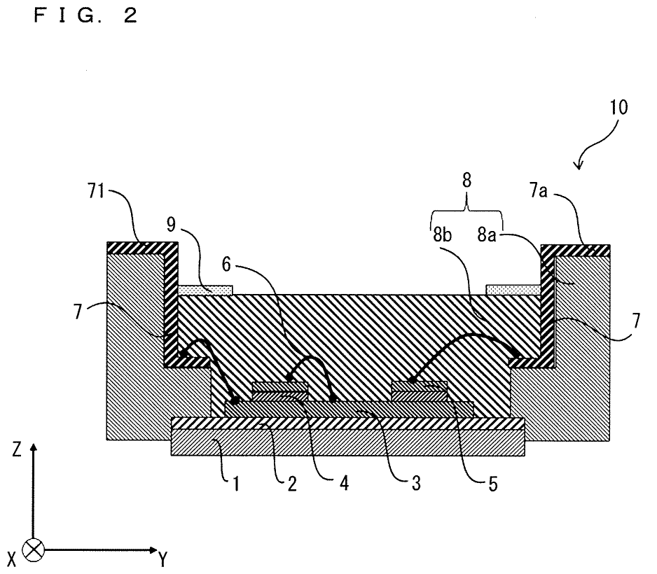

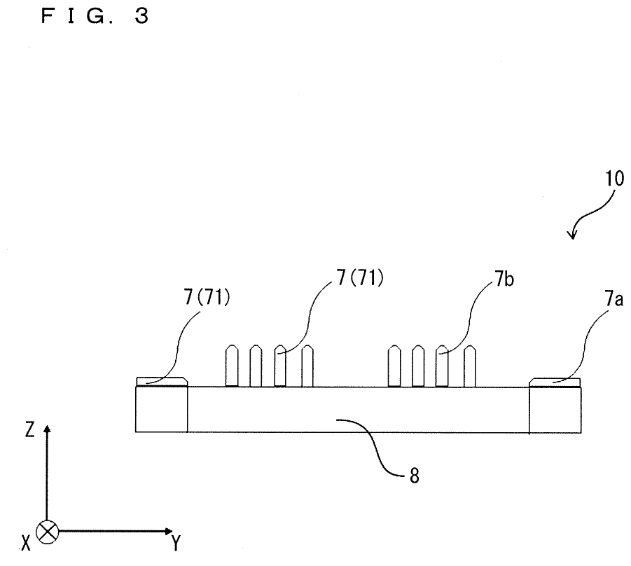

A first preferred embodiment is described below, with reference to the drawings. FIG. 1 is a schematic top view of a semiconductor device 10 according to the first preferred embodiment. FIG. 2 is a schematic cross-sectional view of the semiconductor device 10 according to the first preferred embodiment. FIG. 3 is a schematic side view of the semiconductor device 10 according to the first preferred embodiment. Note that FIG. 2 shows a cross-section taken along the dotted line X-X defined in FIG. 1. Note that the dotted line and the dashed lines in FIG. 1 do not indicate identification portions 9. Further, the schematic side view shown in FIG. 3 is a view of the semiconductor device 10 as viewed from the negative side of the X-axis. Furthermore, as long as there is no particular mention, other schematic side views described later are also assumed to be views of the semiconductor device 10 as viewed from the negative side of the X-axis.

Referring to FIGS. 1 to 3, an example configuration of the semiconductor device 10 is described. The semiconductor device 10 includes a semiconductor element 5, a terminal 7, a resin portion 8, and an identification portion 9. Note that, in the following description, the semiconductor device 10 is assumed to have a module structure, but even in a discrete structure, the present invention can be applied in a case where terminals of different shapes coexist in one package, or where there is a portion in which the distances between terminals led out of the package are not uniform in the single package.

As shown in FIG. 2, a heatsink 1 may be provided. The heatsink 1 is formed with a material having electrical conductivity and thermal conductivity. The heatsink 1 is formed with a metal material such as copper or aluminum.

As shown in FIG. 2, an insulating substrate 2 may be provided on the upper surface of heatsink 1. The insulating substrate 2 is mounted on the upper surface of the heatsink 1 with solder or the like. The insulating substrate 2 is formed with a resin having insulating properties, such as ceramic.

As shown in FIG. 2, a metal pattern 3 may be provided on the upper surface of the insulating substrate 2. The metal pattern 3 is mounted on the upper surface of the insulating substrate 2 with solder or the like. The metal pattern 3 is formed with a highly conductive metal such as copper.

As shown in FIG. 2, the semiconductor element 5 is provided. The semiconductor element 5 is mounted on the metal pattern 3 by a joining layer 4 formed with solder or the like. The semiconductor element 5 may be formed with Si, or may be formed with SiC, GaN, Ga₂O₃, or the like, which is a wide bandgap semiconductor. Note that the device type of the semiconductor element 5 is not necessarily limited to a particular one, but may be a switching element such as an insulated gate bipolar transistor (IGBT) or a metal oxide semiconductor field effect transistor (MOSFET), or may be a freewheeling element. Furthermore, as shown in FIG. 2, a plurality of the semiconductor elements 5 is provided, and the number of the semiconductor elements 5 can be changed as appropriate, depending on the circuit configuration of the semiconductor device 10. Further, the respective semiconductor elements 5 may be electrically connected to the terminals 7, and, as illustrated in FIG. 2, the semiconductor elements 5 and the terminals 7 may be electrically connected by wires 6. Also, as illustrated in FIG. 2, the wires 6 may directly connect the semiconductor elements 5 and the terminals 7, or may connect the semiconductor elements 5 and the terminals 7 via the metal pattern 3.

Specifically, each semiconductor element 5 is electrically connected to the terminal 7 at an electrode portion. A main electrode of the semiconductor element 5 is electrically connected to the terminal 7. For example, in a case where the semiconductor element 5 is a MOSFET, a drain electrode of the semiconductor element 5 is connected to a drain terminal, and a source electrode of the semiconductor element 5 is connected to a source terminal. Also, a control electrode of the semiconductor element 5 is electrically connected to the terminal 7. For example, a gate electrode of the semiconductor element 5 is connected to a gate terminal. The number of electrodes of a semiconductor element 5 can be changed depending on the number of semiconductor elements 5. Note that the control electrode is not necessarily a gate electrode (a gate pad) to which a gate drive voltage for controlling switching on and off of the semiconductor element 5 is applied, and may be a current sense pad, a voltage sense pad, a Kelvin source pad, or a temperature sense diode pad, for example. The current sense pad is a control pad for sensing a current flowing in the cell region of the semiconductor element 5. Specifically, the current sense pad is a control pad that is electrically connected to part of the cell region so that, when a current flows in the cell region of the semiconductor element 5, a current ranging from a fraction of the current flowing in the entire cell region to several tens of thousandths of the current flows in the control pad. The voltage sense pad is another control pad electrically connected to the drain (collector) region to detect a saturation voltage when a current flows in the semiconductor element 5. The Kelvin source pad is a control pad to which the gate drive voltage for controlling switching on and off of the semiconductor element 5 is applied. The temperature sense diode pad is a control pad electrically connected to an anode and a cathode of a temperature sense diode (not shown) provided in the semiconductor element 5. As the voltage between the anode and the cathode of the temperature sense diode provided in the cell region is measured, the temperature of the semiconductor element 5 is measured. Alternatively, a thermistor may be used in place of the temperature sense diode of the semiconductor element 5, and, in that case, control pads corresponding to the anode and the cathode of the temperature sense diode are also provided.

As shown in FIGS. 1 to 3, the terminals 7 are provided. A plurality of terminals 7 is provided. As shown in FIG. 2, one end of each of the terminals 7 is electrically connected to the semiconductor element 5, and, as shown in FIGS. 1 to 3, the other end of each of the terminals 7 is exposed through the surface of the resin portion 8. Specifically, one end of each of the plurality of terminals 7 is electrically connected to the above-mentioned electrode portion of the semiconductor element 5. The portion at which the other end of each of the plurality of terminals 7 is exposed through the surface of the resin portion 8 is an exposed portion 71. Note that, as shown in FIGS. 1 and 3, the terminals 7 may include first terminals 7a and second terminals 7b having a different shape from that of the first terminals 7a. The first terminals 7a are provided so as to extend in the Y-axis direction along the surface of the resin portion 8. The second terminals 7b are provided so as to extend in the Z-axis direction from the surface of the resin portion 8. Further, the distances among the plurality of terminals 7 may be non-uniform.

As shown in FIG. 1 to 3, the resin portion 8 is provided. The resin portion 8 is provided so as to cover the semiconductor element 5 and parts of the terminals 7. The resin portion 8 is formed with at least one of a case member 8a and a sealing member 8b. In the present preferred embodiment, the resin portion 8 is formed with both the case member 8a and the sealing member 8b, as shown in FIGS. 1 and 2. The case member 8a is formed with a resin having insulating properties, and is joined to the heatsink 1. Also, as illustrated in FIG. 2, the case member 8a may be provided so as to surround the outer periphery of the insulating substrate 2 or the like disposed on heatsink 1. The sealing member 8b is provided so as to seal at least the semiconductor element 5 and parts of the terminals 7 in the semiconductor device 10. As shown in FIGS. 1 and 2, in the present preferred embodiment, the sealing member 8b is disposed on the inner side of the case member 8a. The sealing member 8b is formed with gel or resin having insulating properties.

As shown in FIGS. 1 and 2, the identification portion 9 is provided. The identification portion 9 is disposed on the surface of the resin portion 8. The identification portion 9 has a function that can identify the position of the exposed portion 71 of each of the plurality of terminals 7. Also, the identification portion 9 of the present preferred embodiment further has a function that can identify the type of each of the plurality of terminals 7. Furthermore, the identification portion 9 of the present preferred embodiment is disposed on a surface of the sealing member 8b of the resin portion 8, and is disposed on the upper surface of the sealing member 8b.

Meanwhile, as illustrated in FIG. 1, the identification portions 9 may include first identification portions 9a having a function that can identify the types of the respective terminals of the plurality of terminals 7, and second identification portions 9b having a function that can identify any direction. One first identification portion 9a and one second identification portion 9b are provided on the upper surface of the resin portion 8 for each of the plurality of terminals 7.

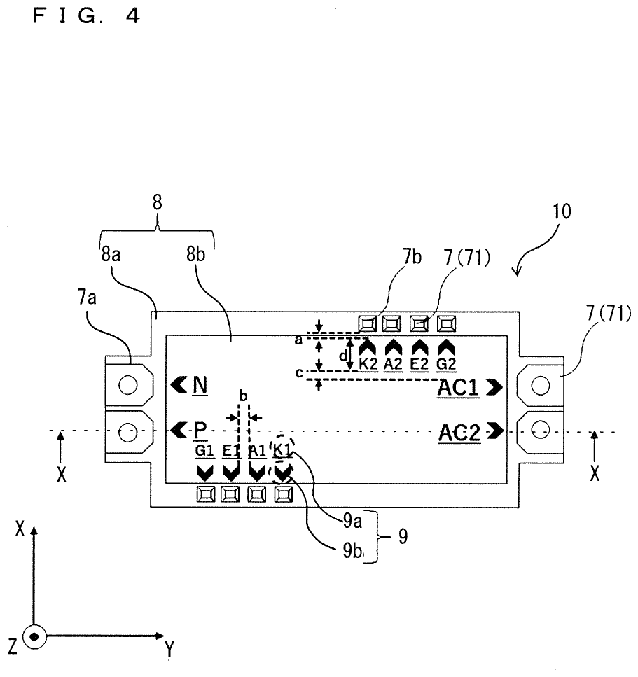

In a case where one identification portion 9 is provided on the upper surface of the resin portion 8 for each one terminal of the plurality of terminals 7, it is desirable to provide each identification portion 9 so that it will be easy to determine to which terminal 7 the identification portion 9 corresponds. As illustrated in FIG. 4, it is preferable that a distance a between a probe contact position that is a position at which a probe comes into contact in the exposed portion 71 of each terminal 7 (this position will be hereinafter referred to as simply the “probe contact position” in some cases) and the identification portion 9 provided for the corresponding terminal 7 is shortened to such an extent that it can be determined to which terminal 7 each of the identification portions 9 corresponds, and a distance b between the identification portions 9 corresponding to the terminals 7 of the same type and a distance c between the identification portions 9 corresponding to the terminals 7 of different types are made longer. For example, the distance c is preferably longer than a distance d between the upper end of a first identification portion 9a and the lower end of a second identification portion 9b corresponding to the first identification portion 9a.

Also, the distance a may vary with each type of the terminals 7, but is preferably an equal distance regardless of the types of the terminals 7. Note that, in a case where the first terminals 7a are provided so as to extend in the X-axis direction or the Y-axis direction along the surface of the resin portion 8, the probe contact positions are desired to be set on the outer peripheral direction side of the semiconductor device 10 in the exposed portions 71 of the first terminals 7a. In this case, each second identification portion 9b is provided in the resin portion 8, and therefore, there is a possibility that the distance a between the probe contact position of each first terminal 7a and the second identification portion 9b corresponding to the first terminal 7a will become longer. In that case, the second identification portions 9b corresponding to the second terminals 7b are provided on the center direction side of the semiconductor device 10, so that the distance a between the probe contact positions of the first terminals 7a and the second identification portions 9b corresponding to the first terminals 7a, and the distance a between the probe contact positions of the second terminals 7b and the second identification portions 9b corresponding to the second terminals 7b become the same.

As illustrated in FIG. 1, the first identification portions 9a may be formed with different characters depending on the types (collector terminal, emitter terminal, gate terminal, and the like) of the plurality of terminals 7. Note that the first identification portions 9a are only required to have a function of identifying the respective types of the plurality of terminals 7, and may be formed with different figures depending on the types of the plurality of terminals 7, or may be formed with different colors depending on the types of the plurality of terminals 7.

As illustrated in FIG. 1, the second identification portions 9b may have a shape from which any direction can be easily identified. As illustrated in FIG. 1, each second identification portion 9b may be formed with an arrow, or may be formed with a triangle, for example. The second identification portions 9b are disposed so as to indicate the positions of the exposed portions 71 of the corresponding terminals 7. As illustrated in FIG. 1, in the present preferred embodiment, the second identification portions 9b are disposed on the inner side of the exposed portions 71 of the terminals 7, and accordingly, the second identification portions 9b are disposed so as to point in the outer peripheral direction of the resin portion 8. As illustrated in FIG. 1, in a case where the second identification portions 9b are disposed on the upper surface of the resin portion 8, an inspection apparatus can identify the probe contact positions of the terminals 7 in the X-axis direction and the Y-axis direction by identifying the direction from the second identification portions 9b. Also, the second identification portions 9b preferably have a shape from which a reference position can be easily identified. For example, as illustrated in FIG. 1, a reference line may be provided on the upper side or the lower side of each first identification portion 9a. Further, the first identification portions 9a may be disposed on the inner side of the second identification portions 9b, but the first identification portions 9a may be disposed on the outer side of the second identification portions 9b.

The semiconductor device 10 of the present preferred embodiment is formed as described above. As the identification portions 9 that are disposed on the surface of the resin portion 8 and from which the positions of the respective exposed portions 71 of the plurality of terminals 7 can be identified are included in a semiconductor device, an inspection apparatus can recognize the accurate positions of the respective terminals 7, and accurately move an inspection jig to the positions of the respective terminals 7 in a case where the semiconductor device has a structure in which terminals having different shapes coexist in one package or a structure in which the distances between the terminals drawn out of the package are not uniform in a portion in the single package. The reason for this is described below.

In a conventional semiconductor device, the index mark is provided only at a position corresponding to a certain terminal. Because of this, in a case where a semiconductor device has a structure in which terminals having different shapes coexist in one package or a structure in which the distances between the terminals drawn out of the package are not uniform in a portion in the single package, an inspection apparatus can recognize the position of the index mark, but cannot recognize the accurate relative position of each terminal, and therefore, cannot accurately move a probe to the position of each terminal. In view of this, it is necessary to set the coordinates of the plurality of terminals 7 beforehand on the inspection apparatus side, and move the probe to the position of each terminal on the basis of the set coordinates.

On the other hand, the semiconductor device 10 of the present preferred embodiment includes the identification portions 9 capable of identifying the positions of the respective exposed portions 71 of the plurality of terminals 7. Thus, the inspection apparatus can recognize the accurate position of each terminal 7 and accurately move the probe to the position of each terminal 7 even in a case where terminals having different shapes coexist in one package, or where there is a portion in which the distances between the terminals drawn out of the package are not uniform in the single package. Accordingly, it is not necessary to set the coordinates of the plurality of terminals 7 beforehand on the inspection apparatus side, and thus, the control program to be used in the inspection apparatus can be simplified.

Also, as described above, in a case where the identification portions 9 are provided on the upper surface of the resin portion 8 for the respective terminals of the plurality of terminals 7, respectively, it is desirable to provide each identification portion 9 so that it will be easy to determine to which terminal 7 the identification portion 9 corresponds. As a result, the inspection apparatus can easily recognize to which terminal 7 each detected identification portion 9 corresponds, and thus, a probe can be more accurately moved to the position of each terminal 7.

Further, as described above, the distance a between the probe contact position of a terminal 7 and the identification portion 9 corresponding to the terminal 7 is preferably constant, regardless of the types of the terminals 7. This eliminates the need to set the distance a preset on the inspection apparatus side, for each type of the terminals 7, and the control program to be used in the inspection apparatus can be simplified.

Also, as described above, the identification portions 9 may further have a function of identifying the respective types of the plurality of terminals 7. This eliminates the need to set which probe is connected to which terminal 7 beforehand on the inspection apparatus side, and the control program to be used in the inspection apparatus can be simplified. Note that, what kind of terminal shape each of the plurality of terminals 7 has may be set on the inspection apparatus side, so that, when the inspection apparatus identifies the type of each of the plurality of terminals 7, the terminal shapes of the plurality of terminals 7 can be collectively identified. Further, the probe contact position for each terminal shape may be set beforehand on the inspection apparatus side, so that, when the inspection apparatus identifies the terminal shape of each of the plurality of terminals 7, the probe contact position for each terminal shape can be identified. A case where the semiconductor device has a structure in which terminals having different shapes coexist in one package, and the probe contact position is to be identified for each terminal shape is now described herein. For example, in a case where each second terminal 7b has a shape extending in the Z-axis direction, and the upper end portion of the second terminal 7b in the Z-axis direction is to be identified as the probe contact position, when the second identification portions 9b are disposed on the upper surface of the resin portion 8, the inspection apparatus can identify the probe contact positions of the second terminals 7b in the X-axis or Y-axis direction as described above, but cannot identify the probe contact positions of the second terminals 7b in the Z-axis direction. Therefore, the inspection apparatus is designed to be capable of identifying the respective terminal shapes of the plurality of terminals 7 from the first identification portions 9a and identifying the probe contact position for each terminal shape, so that the inspection apparatus can also identify the probe contact positions of the second terminals 7b in the Z-axis direction.

Next, a method of manufacturing the semiconductor device 10 according to the present preferred embodiment is described. The method of manufacturing the semiconductor device 10 according to the present preferred embodiment is basically the same as a conventional method of manufacturing a semiconductor device, and therefore, explanation of part of it is not made herein.

The method of manufacturing the semiconductor device 10 includes a connecting process, a resin portion forming process, an identification portion forming process, and an inspecting process.

First, the connecting process is described. In the connecting process, one end of each of the plurality of terminals 7 is electrically connected to the semiconductor element 5.

Next, the resin portion forming process is described. In the resin portion forming process, the resin portion 8 covering the plurality of semiconductor elements 5 and parts of the plurality of terminals 7 is formed so as to expose the other end of each of the plurality of terminals 7 through its surface. In the present preferred embodiment, the sealing member 8b covers the plurality of semiconductor elements 5 and parts of the plurality of terminals 7 so as to expose the other end of each of the plurality of terminals 7 through the surface.

Next, the identification portion forming process is described. In the identification portion forming process, the identification portions 9 having a function of identifying the positions of the exposed portions 71 at which the respective other ends of the plurality of terminals 7 are exposed through the surface of the resin portion 8 are formed on the surface of the resin portion 8. In the present preferred embodiment, the identification portions 9 are formed on the surface of the sealing member 8b of the resin portion 8. For example, the identification portions 9 are formed by printing the identification portions 9 on the surface of the resin portion 8 by a method such as screen printing. Alternatively, the identification portions 9 may be formed by printing the identification portions 9 on the surface of the resin portion 8 by a method using a laser, may be formed by attaching the identification portions 9 to the surface of the resin portion 8 by a method of attaching a sealing material, or may be formed by processing the surface of the resin portion 8 by a method of performing embossing at the time of molding the resin portion 8.

Next, the inspecting process is described. In the inspecting process, a probe is brought into contact with each terminal 7, and electrical current is applied from the probe to the terminal 7. In this manner, the electrical characteristics of the semiconductor device 10 are inspected. This will be described later in detail.

Through the processes, the semiconductor device 10 is manufactured. As described above, the method of manufacturing the semiconductor device 10 according to the present preferred embodiment includes the identification portion forming process to form the identification portions from which the positions of the respective exposed portions 71 of the plurality of terminals can be identified. With this arrangement, even in a case where the semiconductor device has a structure in which terminals having different shapes coexist in one package or a structure in which the distances between the terminals drawn out of the package are not uniform in a portion in the single package, the inspection apparatus in the inspecting process can recognize the accurate positions of the respective terminals 7, and accurately move an inspection jig to the positions of the respective terminals 7.

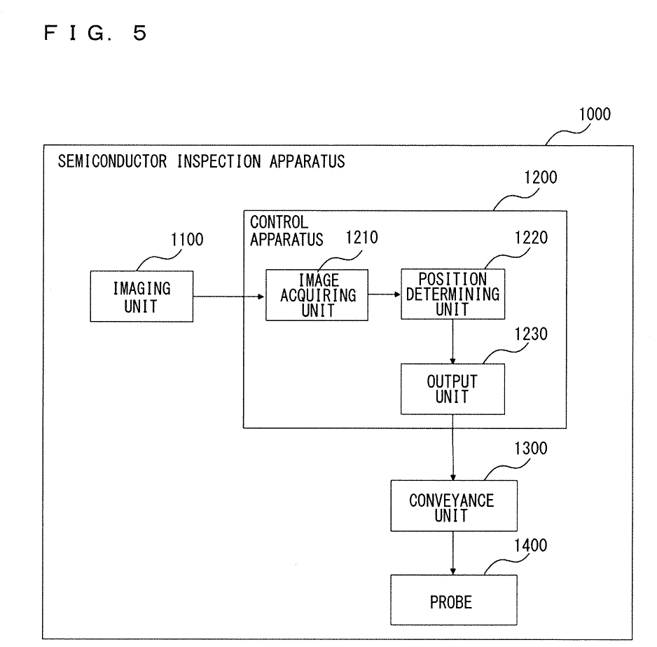

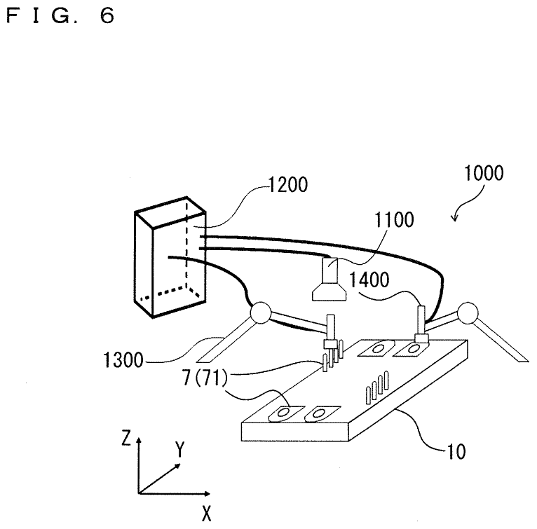

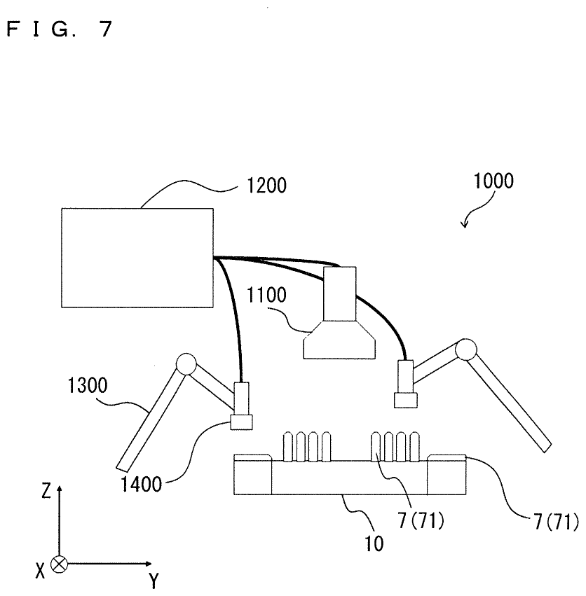

Next, an example of a basic configuration of a semiconductor inspection apparatus 1000 that inspects the electrical characteristics of the semiconductor device 10 is described with reference to FIGS. 5 to 7. FIG. 5 is a configuration diagram illustrating an example of a basic configuration of the semiconductor inspection apparatus 1000. FIG. 6 is a schematic perspective view illustrating an example of a basic configuration of the semiconductor inspection apparatus 1000. FIG. 7 is a schematic side view illustrating an example of a basic configuration of the semiconductor inspection apparatus 1000. The semiconductor inspection apparatus 1000 is used in the inspecting process in the process of manufacturing the semiconductor device 10 described above. Also, the semiconductor inspection apparatus 1000 described below is a flying probe tester, for example.

The semiconductor inspection apparatus 1000 includes an imaging unit 1100, a control apparatus 1200, a conveyance unit 1300, and a probe 1400.

The imaging unit 1100 captures an image of the identification portions 9 of the semiconductor device 10, and outputs the captured image to the control apparatus 1200. Since the identification portions 9 are disposed on the upper surface of the semiconductor device 10 in the present preferred embodiment, the imaging unit 1100 images the semiconductor device 10 from the upper surface as illustrated in FIGS. 6 and 7. That is, the imaging unit 1100 images the semiconductor device 10 from the positive side of the Z-axis direction. Note that the imaging unit 1100 of the present preferred embodiment is formed with one camera, the imaging range of the one camera is a range in which the entire upper surface of the semiconductor device 10 falls, and the camera is disposed and fixed on the positive side of the Z-axis direction with respect to the upper surface of the semiconductor device 10. Note that, in a case where the imaging range of the one camera is a range in which part of the upper surface of the semiconductor device 10 falls, the camera may be provided to be movable in the X-axis direction and the Y-axis direction, for example. Also, in a case where the imaging range of one camera is a range in which part of the upper surface of the semiconductor device 10 falls, a plurality of cameras may be provided and fixed.

The control apparatus 1200 includes an image acquiring unit 1210, a position determining unit 1220, and an output unit 1230. The image acquiring unit 1210 acquires the captured image output from the imaging unit 1100.

On the basis of the captured image acquired by the image acquiring unit 1210, the position determining unit 1220 determines contact positions (synonymous with the above-mentioned “probe contact positions”) at which the probe 1400 is brought into contact with the terminals 7 of the semiconductor device 10. Specifically, the identification portions 9 are detected from the captured image, the positions of the exposed portions 71 of the terminals 7 are identified from the identification portions 9, and the contact positions at which the probe 1400 is brought into contact with the terminals 7 are determined on the basis of the identified positions of the exposed portions 71 of the terminals 7.

The output unit 1230 outputs the contact positions determined by the position determining unit 1220 to the conveyance unit 1300.

The conveyance unit 1300 moves the probe 1400 to each contact position, on the basis of the contact positions output from the output unit 1230.

The probe 1400 is moved to a contact position by the conveyance unit 1300, is brought into contact with the terminal 7, and applies electrical current from the probe 1400 to the terminal 7, to inspect the electrical characteristics of the semiconductor device 10.

The semiconductor inspection apparatus 1000 according to the present preferred embodiment is designed as described above.

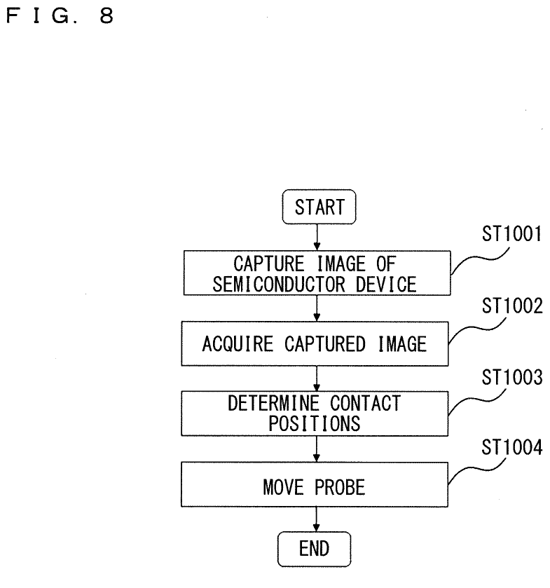

Next, an operation of the semiconductor inspection apparatus 1000 is described with reference to FIG. 8. FIG. 8 is a flowchart showing an operation flow of the semiconductor inspection apparatus 1000.

When the control apparatus 1200 receives a command to start processing from the outside, the semiconductor inspection apparatus 1000 starts the processing illustrated in FIG. 8. (Start)

In step ST1001, the imaging unit 1100 captures an image of the surface of the resin portion 8, and outputs the captured image.

Next, in step ST1002, the image acquiring unit 1210 acquires the captured image output from the imaging unit 1100.

Next, in step ST1003, the position determining unit 1220 detects the identification portions 9 from the captured image acquired by the image acquiring unit 1210, identifies the positions of the exposed portions 71 at which the other ends of the terminals 7 are exposed through the surface of the resin portion 8 from the identification portions 9, and determines the contact positions at which the probe 1400 is to be brought into contact with the terminals 7, on the basis of the identified positions of the exposed portions 71 of the terminals 7.

Next, in step ST1004, the output unit 1230 outputs the contact positions determined by the position determining unit 1220, and the conveyance unit 1300 moves the probe 1400 to the contact positions, on the basis of the contact positions output from the output unit 1230. The probe 1400 and each terminal 7 are brought into contact with each other, and electrical current is applied from the probe 1400 to the terminal 7, so that the electrical characteristics of the semiconductor device 10 are inspected.

When the processing proceeds to step ST1004, the processing illustrated in FIG. 8 comes to an end. (End)

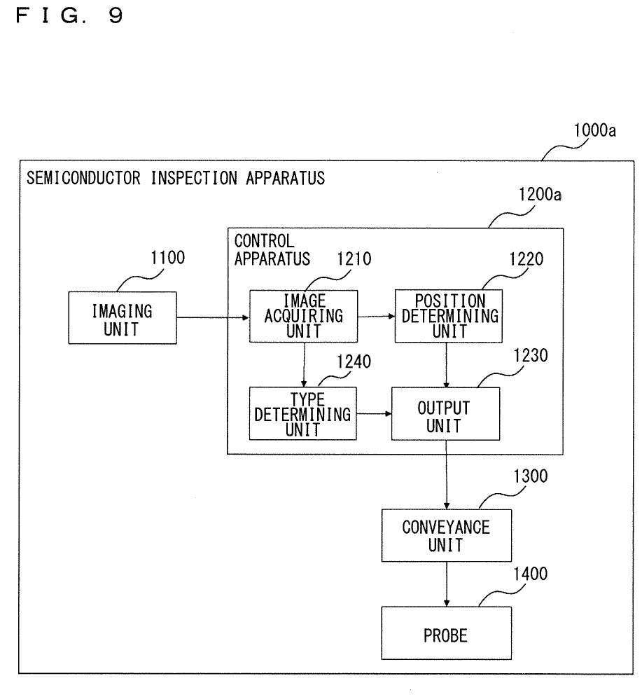

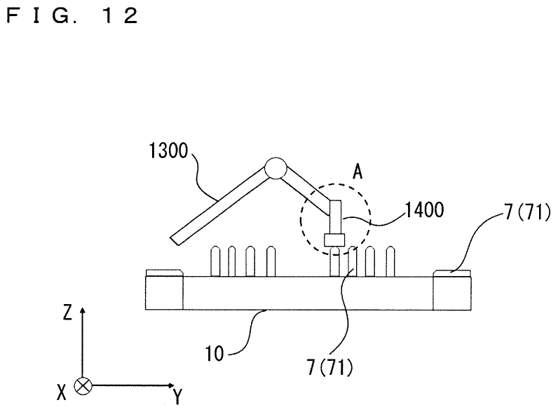

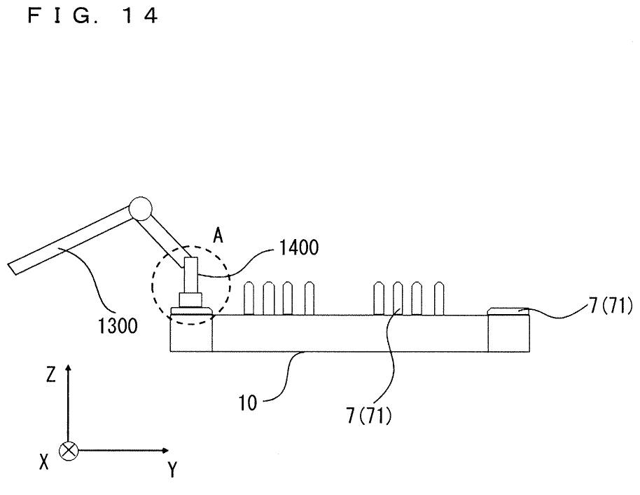

Next, an example of a specific configuration of the semiconductor inspection apparatus 1000 that inspects the electrical characteristics of the semiconductor device 10 is described with reference to FIGS. 9 to 18.

First, a first example of a specific configuration of the semiconductor inspection apparatus 1000 is described with reference to FIG. 9. FIG. 9 is a configuration diagram illustrating the first example of a specific configuration of the semiconductor inspection apparatus 1000. The semiconductor inspection apparatus 1000 having the first example configuration is referred to as a semiconductor inspection apparatus 1000a.

The semiconductor inspection apparatus 1000a inspects the electrical characteristics of the semiconductor device 10 including the identification portions 9 having both a function of identifying the positions of the exposed portions 71 at which the respective other ends of the plurality of terminals 7 are exposed through the surface of the resin portion 8 and a function of identifying the type of each of the plurality of terminals 7.

As illustrated in FIG. 9, in the semiconductor inspection apparatus 1000a, a control apparatus 1200a further includes a type determining unit 1240.

On the basis of a captured image acquired by the image acquiring unit 1210, the type determining unit 1240 determines the type of each probe 1400 to be brought into contact with the terminals 7 of the semiconductor device 10. Specifically, the identification portions 9 are detected from the captured image, the type of each terminal 7 is identified from the identification portions 9, and the probe type of the probe 1400 to be brought into contact with the terminal 7 is determined on the basis of the identified type of the terminal 7.

The output unit 1230 outputs the contact positions determined by the position determining unit 1220 and the probe type of the probe 1400 determined by the type determining unit 1240 to the conveyance unit 1300.

The conveyance unit 1300 moves the determined probe 1400 to each contact position, on the basis of the contact positions and the probe type output from the output unit 1230.

The probe 1400 is moved to a contact position by the conveyance unit 1300, is brought into contact with the terminal 7, and applies electrical current from the probe 1400 to the terminal 7, to inspect the electrical characteristics of the semiconductor device 10.

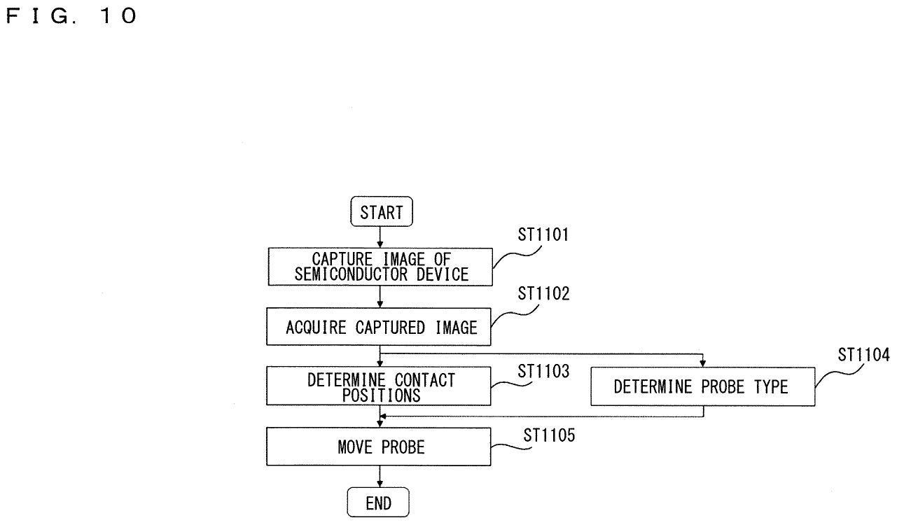

Next, an operation of the semiconductor inspection apparatus 1000a is described with reference to FIG. 10. FIG. 10 is a flowchart showing an operation flow of the semiconductor inspection apparatus 1000a.

When the control apparatus 1200a receives a command to start processing from the outside, the semiconductor inspection apparatus 1000a starts the processing illustrated in FIG. 10. (Start)

In step ST1101, the imaging unit 1100 captures an image of the surface of the resin portion 8, and outputs the captured image.

Next, in step ST1102, the image acquiring unit 1210 acquires the captured image output from the imaging unit 1100.

Next, in step ST1103, the position determining unit 1220 detects the identification portions 9 from the captured image acquired by the image acquiring unit 1210, identifies the positions of the exposed portions 71 at which the other ends of the terminals 7 are exposed through the surface of the resin portion 8 from the identification portions 9, and determines the contact positions at which the probe 1400 is to be brought into contact with the terminals 7, on the basis of the identified positions of the exposed portions 71 of the terminals 7.

Further, in step ST1104, the type determining unit 1240 detects the identification portions 9 from the captured image, identifies the type of each terminal 7 from the identification portions 9, and determines the probe type of the probe 1400 to be brought into contact with the terminal 7, on the basis of the identified type of the terminal 7.

Next, in step ST1105, the output unit 1230 outputs the contact positions determined by the position determining unit 1220 and the probe type of the probe 1400 determined by the type determining unit 1240, and the conveyance unit 1300 moves the determined probe 1400 to each contact position on the basis of the contact positions and the probe type output from the output unit 1230. The probe 1400 and each terminal 7 are brought into contact with each other, and electrical current is applied from the probe 1400 to the terminal 7, so that the electrical characteristics of the semiconductor device 10 are inspected.

When the processing proceeds to step ST1105, the processing illustrated in FIG. 10 comes to an end. (End)

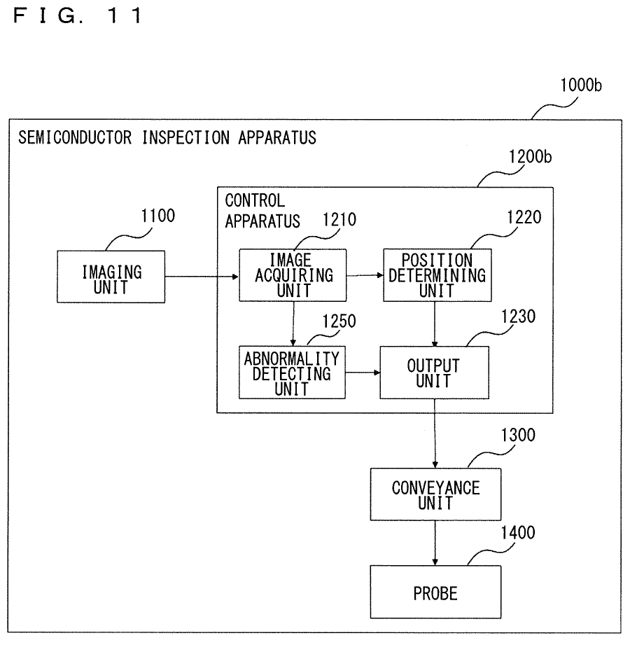

Next, a second example of a specific configuration of the semiconductor inspection apparatus 1000 is described with reference to FIG. 11. FIG. 11 is a configuration diagram illustrating the second example of a specific configuration of the semiconductor inspection apparatus 1000. The semiconductor inspection apparatus 1000 having the second example configuration is referred to as a semiconductor inspection apparatus 1000b.

As illustrated in FIG. 11, in the semiconductor inspection apparatus 1000b, a control apparatus 1200b further includes an abnormality detecting unit 1250.

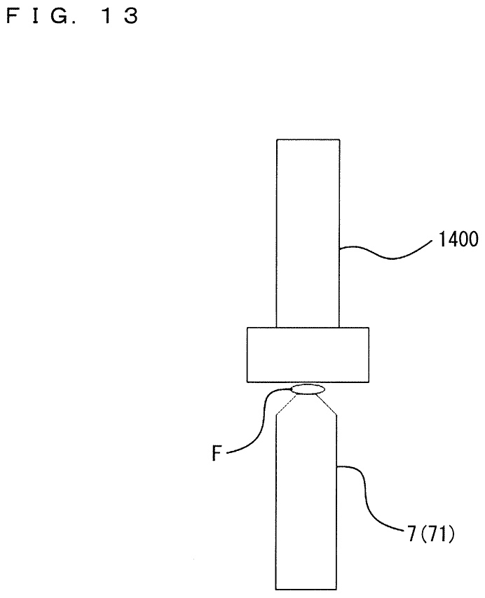

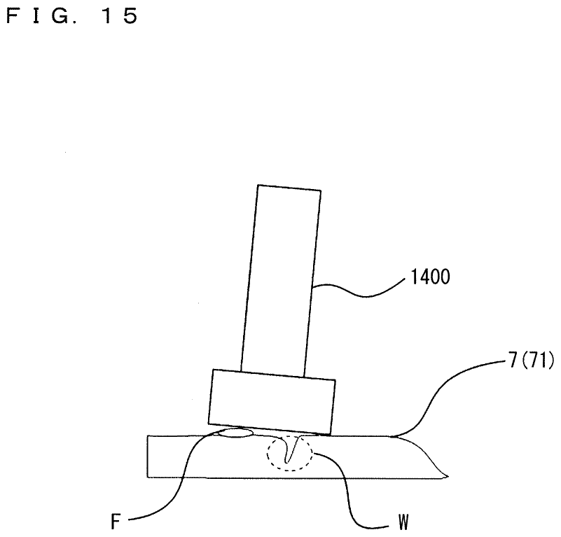

The abnormality detecting unit 1250 detects an abnormality in a terminal 7 of the semiconductor device 10 from a captured image acquired by the image acquiring unit 1210. For example, an abnormality in a terminal 7 is foreign matter F adhering to the terminal 7 as illustrated in FIGS. 13 and 15, a cut W in the terminal 7 as illustrated in FIG. 15, or the like.

In a case where an abnormality in a terminal 7 is detected by the abnormality detecting unit 1250, an external apparatus (not shown) takes a defect-eliminating measure to eliminate the abnormality in the terminal 7.

In a case where any abnormality in a terminal 7 is not detected by the abnormality detecting unit 1250, the output unit 1230 outputs the contact positions determined by the position determining unit 1220, and, in a case where an abnormality in a terminal 7 is detected, the output unit 1230 does not output the contact positions determined by the position determining unit 1220. Note that, in a case where the abnormality detecting unit 1250 does not detect any abnormality in the terminals 7, the position determining unit 1220 may determine the contact positions from a captured image acquired by the image acquiring unit 1210, and, in a case where an abnormality in a terminal 7 is detected, the position determining unit 1220 does not necessarily determine the contact positions from a captured image acquired by the image acquiring unit 1210.

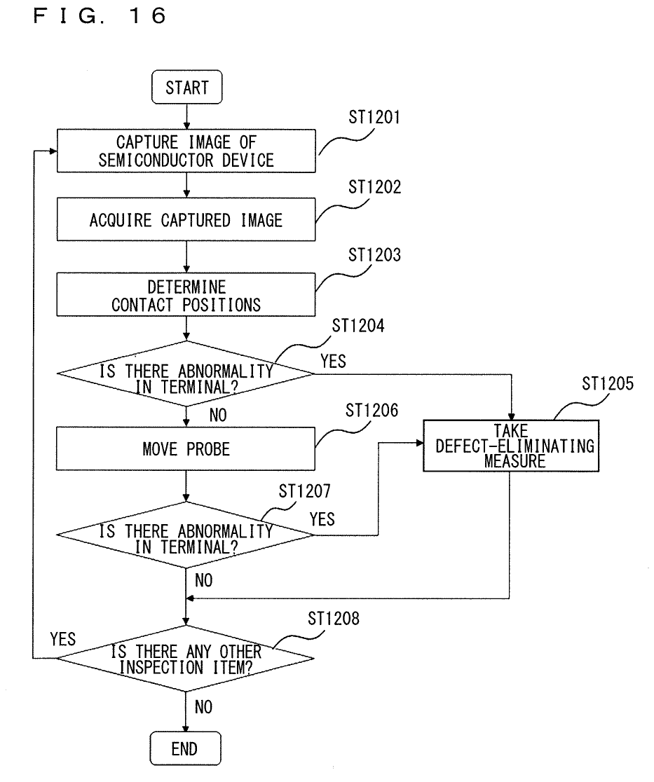

An operation of semiconductor inspection apparatus 1000b including abnormality detecting unit 1250 is now described with reference to FIG. 16. FIG. 16 is a flowchart illustrating an operation flow of the semiconductor inspection apparatus 1000b including the abnormality detecting unit 1250.

When the control apparatus 1200b receives a command to start processing from the outside, the semiconductor inspection apparatus 1000b starts the processing illustrated in FIG. 16. (Start)

In step ST1201, the imaging unit 1100 captures an image of the surface of the resin portion 8, and outputs the captured image.

Next, in step ST1202, the image acquiring unit 1210 acquires the captured image output from the imaging unit 1100.

Next, in step ST1203, the position determining unit 1220 detects the identification portions 9 from the captured image acquired by the image acquiring unit 1210, identifies the positions of the exposed portions 71 at which the other ends of the terminals 7 are exposed through the surface of the resin portion 8 from the identification portions 9, and determines the contact positions at which the probe 1400 is to be brought into contact with the terminals 7, on the basis of the identified positions of the exposed portions 71 of the terminals 7.

Next, in step ST1204, the abnormality detecting unit 1250 detects an abnormality in a terminal 7 from the captured image acquired by the image acquiring unit 1210. If an abnormality in a terminal 7 is detected by the abnormality detecting unit 1250 (“YES” in step ST1204), the processing proceeds to step ST1205, and, if any abnormality among the terminals 7 is not detected (“NO” in step ST1204), the processing proceeds to step ST1206.

In a case where the processing proceeds to step ST1205, an external apparatus (not shown) takes a defect-eliminating measure.

In a case where the processing proceeds to step ST1206, the output unit 1230 outputs the contact positions determined by the position determining unit 1220, and the conveyance unit 1300 moves the probe 1400 to each contact position on the basis of the contact positions output from the output unit 1230. The probe 1400 and each terminal 7 are brought into contact with each other, and electrical current is applied from the probe 1400 to the terminal 7, so that the electrical characteristics of the semiconductor device 10 are inspected.

Next, in step ST1207, the abnormality detecting unit 1250 detects an abnormality in the terminals 7 from the captured image acquired by the image acquiring unit 1210. If an abnormality in a terminal 7 is detected by the abnormality detecting unit 1250 (“YES” in step ST1207), the processing proceeds to step ST1205, and, if any abnormality among the terminals 7 is not detected (“NO” in step ST1207), the processing proceeds to step ST1208. Note that, in step ST1207, an abnormality among the terminals 7 to be detected by the abnormality detecting unit 1250 is, for example, a cut W such as a discharge mark, which might occur when electrical current is applied to the terminals 7 in step ST1206.

In a case where the processing proceeds to step ST1208, the control apparatus 1200b determines whether there is any other inspection item. If it is determined by the control apparatus 1200b that there is another inspection item (“YES” in step ST1208), the processing proceeds to step ST1201, and, if it is determined that there are no more inspection items (“NO” in step ST1208), the processing illustrated in FIG. 16 is ended. (End)

Note that one of step ST1204 or step ST1207 may be omitted.

In the semiconductor inspection apparatus 1000b, the abnormality detecting unit 1250 detects an abnormality among the terminals 7 from a captured image acquired by the image acquiring unit 1210. In a case where any abnormality among the terminals 7 is not detected by the abnormality detecting unit 1250, the output unit 1230 outputs the contact positions determined by the position determining unit 1220, and, in a case where an abnormality in a terminal 7 is detected, the output unit 1230 does not output the contact positions determined by the position determining unit 1220. In this manner, the probe 1400 can be prevented from moving to the contact positions in a case where there is an abnormality among the terminals 7. Thus, electrical current is not applied to the terminal 7 having the abnormality, and it is possible to lower the risk that the semiconductor device 10 will break down due to an abnormal operation. Accordingly, the probe 1400 can be brought into contact with a terminal 7 after confirming that the terminal 7 is normal. Thus, unnecessary trouble in the semiconductor device 10 can be reduced, and productivity of the semiconductor device 10 can be increased. Furthermore, after the probe 1400 is brought into contact with the terminals 7 and the electrical characteristics of the semiconductor device 10 are inspected, the abnormality detecting unit 1250 again detects an abnormality among the terminals 7 from a captured image acquired by the image acquiring unit 1210. Thus, a semiconductor device 10 having a defect caused by the inspection of electrical characteristics can be found at an early stage.

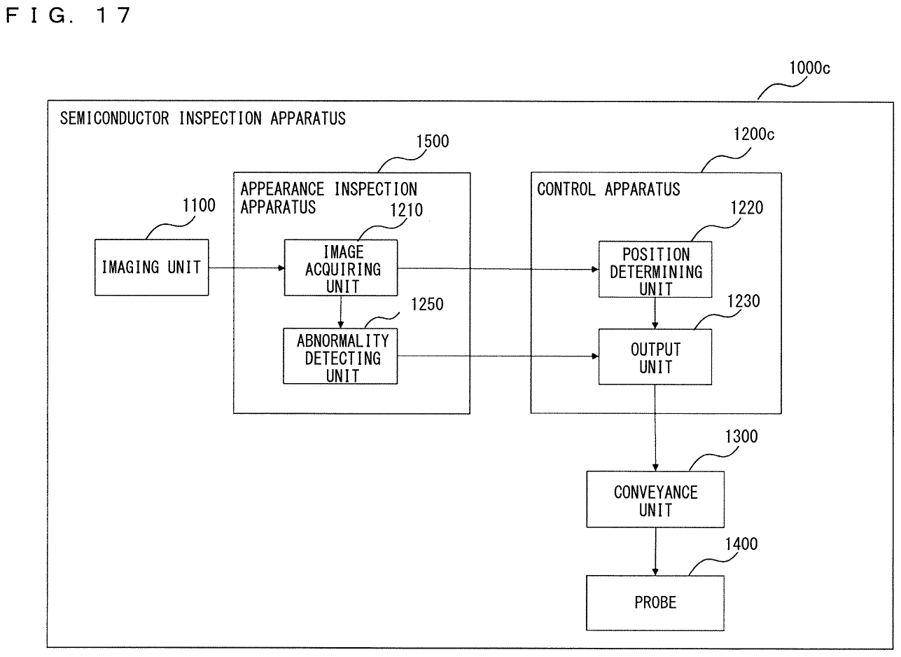

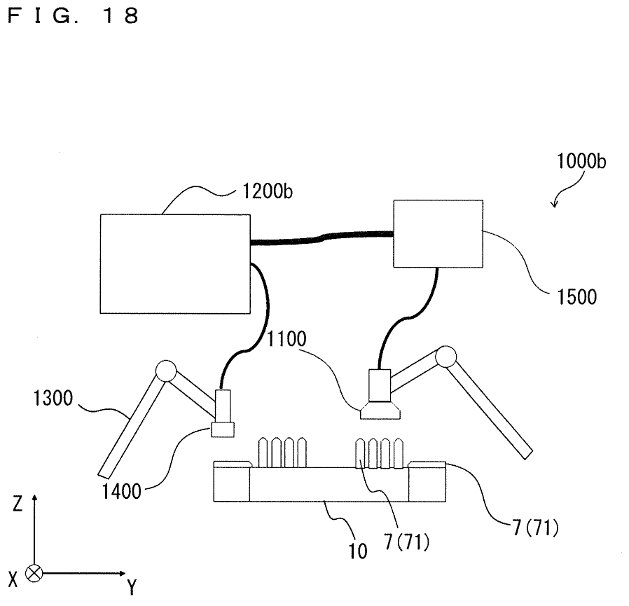

Next, a third example of a specific configuration of the semiconductor inspection apparatus 1000 is described with reference to FIGS. 17 and 18. FIG. 17 is a configuration diagram illustrating the third example of a specific configuration of the semiconductor inspection apparatus 1000. FIG. 18 is a schematic side view illustrating the third example of a specific configuration of the semiconductor inspection apparatus 1000. The semiconductor inspection apparatus 1000 having the third example configuration is referred to as a semiconductor inspection apparatus 1000c.

As illustrated in FIGS. 17 and 18, the semiconductor inspection apparatus 1000c includes an appearance inspection apparatus 1500. In the third example configuration, the image acquiring unit 1210 and the abnormality detecting unit 1250 are included in the appearance inspection apparatus 1500. Further, as illustrated in FIG. 18, the imaging unit 1100 may be connected to the appearance inspection apparatus 1500, and be movable by the conveyance unit 1300.

An operation of the semiconductor inspection apparatus 1000c is similar to that of the semiconductor inspection apparatus 1000b described above, and therefore, explanation thereof is not made herein.

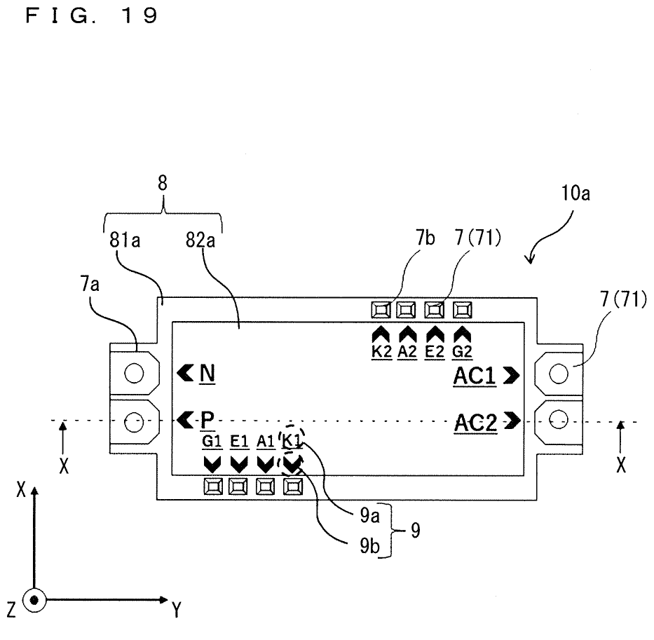

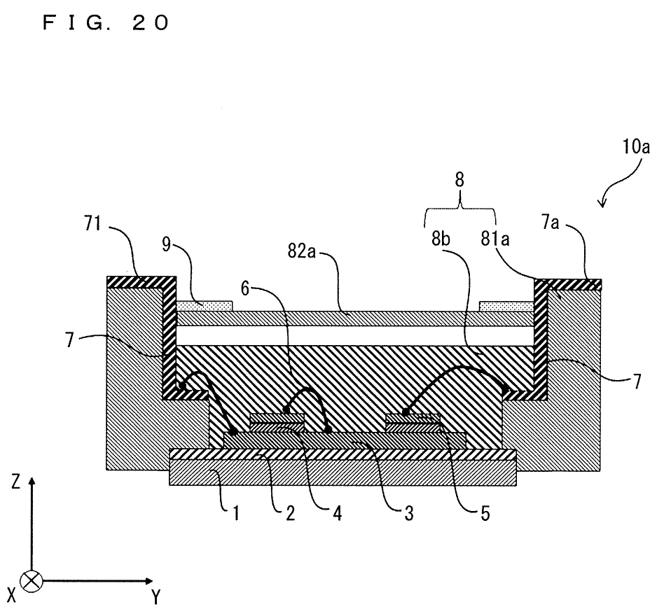

Next, modifications of the first preferred embodiment are described with reference to FIGS. 19 to 21. First, a first modification of the first preferred embodiment is described with reference to FIGS. 19 and 20. FIG. 19 is a schematic top view of a semiconductor device 10a according to the first modification of the first preferred embodiment. FIG. 20 is a schematic cross-sectional view of the semiconductor device 10a according to the first modification of the first preferred embodiment. Note that FIG. 20 shows a cross-section taken along the dotted line X-X defined in FIG. 19. Note that the dotted line and the dashed lines in FIG. 19 do not indicate identification portions 9.

The semiconductor device 10a according to the first modification of the first preferred embodiment differs from the semiconductor device 10 described above in the configuration of the resin portion 8. In the resin portion 8 of the first modification, the case member 8a is formed with a peripheral edge portion 81a and a lid portion 82a. As illustrated in FIGS. 19 and 20, the peripheral edge portion 81a is a portion provided so as to surround the outer periphery of the insulating substrate 2 and the like disposed on the heatsink 1, and the lid portion 82a is a portion provided so as to cover the space surrounded by the peripheral edge portion 81a. In the semiconductor device 10 described above, the case member 8a is formed only with the peripheral edge portion 81a.

As illustrated in FIGS. 19 and 20, the identification portions 9 of the first modification are disposed on the upper surface of the lid portion 82a of the case member 8a.

The semiconductor device 10a of the first modification can achieve the same effects as those of the semiconductor device 10 described above.

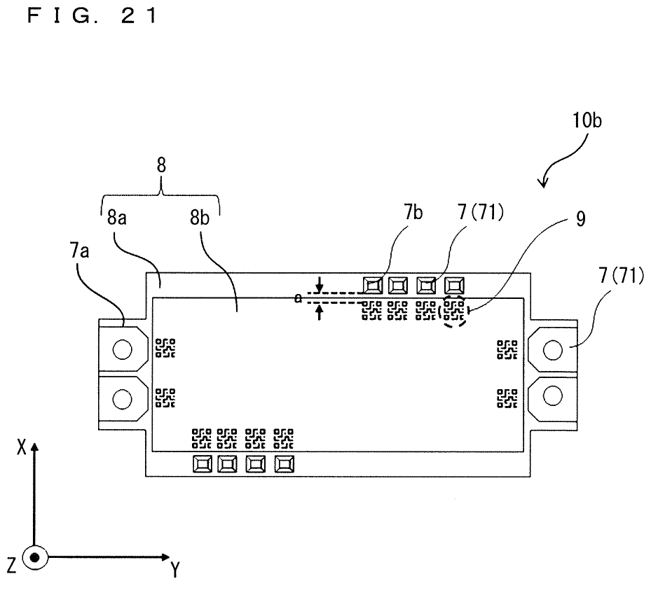

Next, a second modification of the first preferred embodiment is described with reference to FIG. 21. FIG. 21 is a schematic top view of a semiconductor device 10b according to the second modification of the first preferred embodiment. Note that the dashed lines in FIG. 21 do not indicate identification portions 9.

The semiconductor device 10b according to the second modification of the first preferred embodiment differs from the semiconductor device 10 described above in the configuration of the identification portions 9. The identification portions 9 of the second modification are formed with two-dimensional codes. The two-dimensional codes have identification information from which the positions of the respective exposed portions 71 of a plurality of terminals 7 can be identified. Note that, as illustrated in FIG. 21, the two-dimensional codes may be provided on the surface of the resin portion 8, one for each of the plurality of terminals 7. In that case, each two-dimensional code is only required to have the identification information about each corresponding terminal 7. Also, in that case, the distance a between the probe contact position of a terminal 7 and the two-dimensional code corresponding to the terminal 7 is preferably constant, regardless of the types of the terminals 7. Alternatively, only one two-dimensional code may be provided on the surface of the resin portion 8. In that case, the one two-dimensional code is only required to have the identification information about all the plurality of terminals 7. Further, the identification information held in the two-dimensional code may include identification information from which the type of each of the plurality of terminals 7 can be identified, and further include identification information from which the inspection conditions (current value, voltage value, and the like) for inspecting the electrical characteristics of the semiconductor device 10 can be identified.

The semiconductor device 10b of the second modification can achieve the same effects as those of the semiconductor device 10 described above. Further, as the semiconductor device 10b of the second modification can identify the inspection conditions for inspecting the electrical characteristics of the semiconductor device 10 from the identification portions 9, the control apparatus 1200 does not need to set the inspection conditions beforehand, and the control program to be used in the control apparatus 1200 can be simplified.

### Second Preferred Embodiment

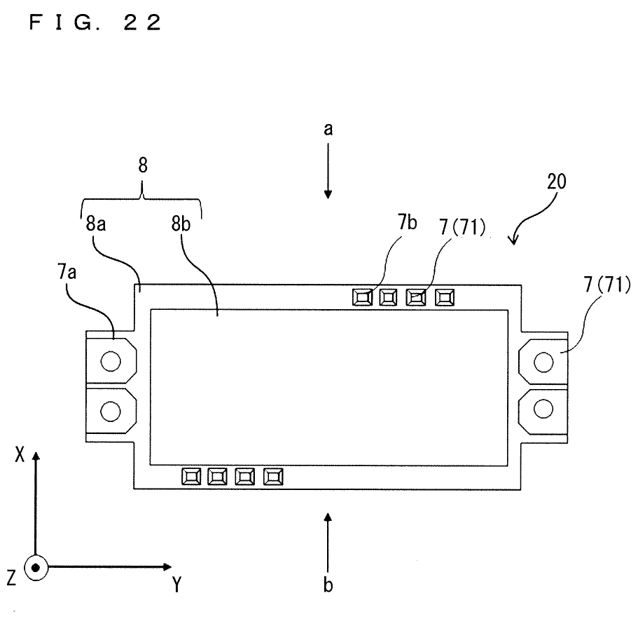

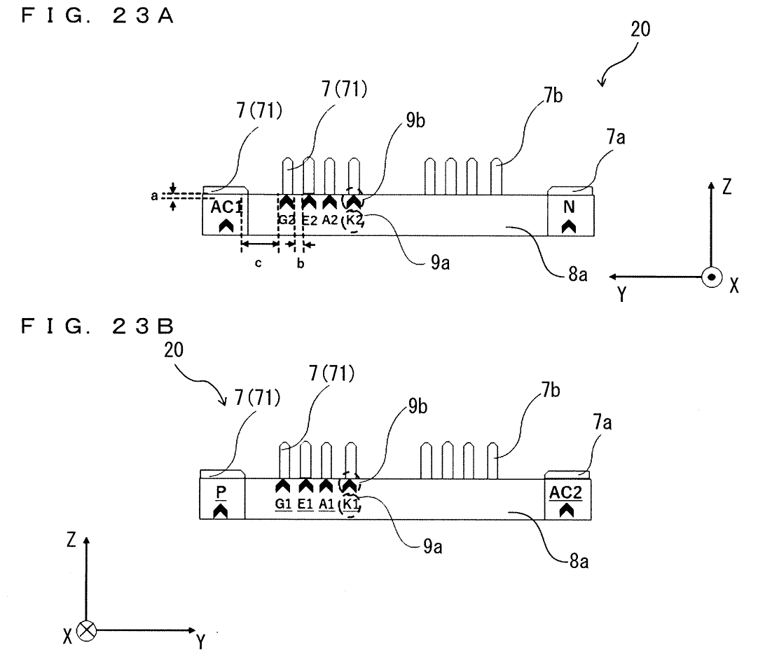

A semiconductor device 20 according to a second preferred embodiment is now described, with reference to FIGS. 22, 23A and 23B. FIG. 22 is a schematic top view of a semiconductor device 20 according to the second preferred embodiment. FIGS. 23A and 23B are schematic side views of the semiconductor device 20 according to the second preferred embodiment. Note that the dashed lines in FIGS. 23A and 23B do not indicate identification portions 9. FIG. 23A is a schematic side view of the semiconductor device 20 illustrated in FIG. 22, as viewed from the positive side of the X-axis direction (direction a). FIG. 23B is a schematic side view of the semiconductor device 20 illustrated in FIG. 22, as viewed from the negative side of the X-axis direction (direction b).

In the semiconductor device 20 of the second preferred embodiment, the identification portions 9 are provided on side surfaces of a resin portion 8. The semiconductor device 10 of the first preferred embodiment has the identification portions 9 disposed on the upper surface of the resin portion 8, but the semiconductor device 20 of the second preferred embodiment differs in that the identification portions 9 are disposed on side surfaces of the resin portion 8. In the second preferred embodiment, as illustrated in FIGS. 23A and 23B, the identification portions 9 are disposed on the side surfaces of the resin portion 8 facing in the X-axis direction. However, the identification portions 9 may be provided on the side surfaces of the resin portion 8 facing in the Y-axis direction. Also, the identification portions 9 may be disposed on both the surfaces facing in the X-axis direction and the surfaces facing in the Y-axis direction among the side surfaces of the resin portion 8. For example, the identification portions 9 corresponding to first terminals 7a may be disposed on the surfaces facing in the Y-axis direction among the side surfaces of the resin portion 8, and the identification portions 9 corresponding to second terminals 7b may be disposed on the surfaces facing in the X-axis direction among the side surfaces of the resin portion 8.

The identification portions 9 may further have a function with which the type of each of a plurality of terminals 7 can be identified. Further, the identification portions 9 of the second preferred embodiment are disposed on surfaces of a case member 8a, but may be disposed on surfaces of a sealing member 8b.

Furthermore, each identification portion 9 may be formed with a first identification portion 9a having a function with which the type of each of the plurality of terminals 7 can be identified and a second identification portion 9b having a function with which any direction can be identified, and one first identification portion 9a and one second identification portion 9b may be provided on each side surface of the resin portion 8 for each of the plurality of terminals 7.

In a case where one identification portion 9 is provided on each of the side surfaces of the resin portion 8 for each of the plurality of terminals 7, it is desirable that each identification portion 9 is provided so that it is easy to determine to which terminal 7 the identification portion 9 corresponds. As illustrated in FIGS. 23A and 23B, it is preferable to shorten the distance a between the probe contact position of a terminal 7 and the identification portion 9 corresponding to the terminal 7 to such an extent that it is possible to determine to which terminal 7 each of the identification portions 9 corresponds, and extend the distance b between the identification portions 9 corresponding to the terminals 7 of the same type and the distance c between the identification portions 9 corresponding to the terminals 7 of different types.

Also, the distance a is preferably constant, regardless of the types of the terminals 7.

As illustrated in FIGS. 23A and 23B, the first identification portions 9a may be formed with different characters depending on the types (collector terminal, emitter terminal, gate terminal, and the like) of the plurality of terminals 7. Note that the first identification portions 9a are only required to have a function of identifying the respective types of the plurality of terminals 7, and may be formed with different figures depending on the types of the plurality of terminals 7, or may be formed with different colors depending on the types of the plurality of terminals 7.

As illustrated in FIGS. 23A and 23B, the second identification portions 9b may have a shape from which any direction can be easily identified. As illustrated in FIGS. 23A and 23B, each second identification portion 9b may be formed with an arrow, or may be formed with a triangle, for example. The second identification portions 9b are disposed so as to indicate the positions of the exposed portions 71 of the corresponding terminals 7. As illustrated in FIGS. 23A and 23B, in the present preferred embodiment, the second identification portions 9b are disposed on the lower side of the positions of the exposed portions 71 of the terminals 7, and accordingly, the second identification portions 9b are disposed so as to point in the upper surface direction of the resin portion 8. As illustrated in FIGS. 23A and 23B, in a case where the second identification portions 9b are disposed on the side surfaces of the resin portion 8, an inspection apparatus can identify the probe contact positions of the terminals 7 in the Y-axis direction and the Z-axis direction by identifying the direction from the second identification portions 9b. Also, the second identification portions 9b preferably have a shape from which a reference position can be easily identified. For example, as illustrated in FIG. 23B, a reference line may be provided on the upper side or the lower side of each first identification portion 9a. Further, as illustrated in FIGS. 23A and 23B, the first identification portions 9a may be disposed on the upper side of the second identification portions 9b, and the first identification portions 9a may be disposed on the lower side of the second identification portions 9b.

Also, the identification portions 9 may be formed with the two-dimensional codes described above.

The semiconductor device 20 of the second preferred embodiment is designed as described above. The identification portions 9 are disposed on the surface of the resin portion 8 as in the first preferred embodiment, so that the same effects as those of the first preferred embodiment can be achieved. Further, in a case where the terminals 7 have a shape extending on the positive side of the Z-axis direction like the second terminals 7b, the probe contact positions of the terminals 7 can be determined from the relative positions with respect to the second identification portions 9b disposed on side surfaces of the resin portion 8. This eliminates the need to set the coordinates in the Z-axis direction beforehand on the side of the control apparatus 1200, and the control program to be used in the control apparatus 1200 can be simplified. Also, as the identification portions 9 are disposed on the side surfaces of the resin portion 8, the distance c between the identification portions 9 corresponding to terminals 7 of different types can be made longer than that in a case where the identification portions 9 are disposed on the upper surface of the resin portion 8, depending on the shape of the resin portion 8 or the dimension of the surface area of the resin portion 8. As a result, the inspection apparatus can easily recognize to which terminal 7 each detected identification portion 9 corresponds, and thus, a probe can be more accurately moved to the position of each terminal 7.

Note that, in the above description, the identification portions 9 are disposed on side surfaces of the resin portion 8. However, the identification portions 9 may be disposed not only on the side surfaces of the resin portion 8 but also on the upper surface of the resin portion 8. For example, the identification portions 9 corresponding to the second terminals 7b having a shape extending toward the positive side of the Z-axis direction may be disposed on the side surfaces of the resin portion 8, and the identification portions 9 corresponding to the first terminals 7a having a shape extending in the X-axis direction may be disposed on the upper surface of the resin portion 8.

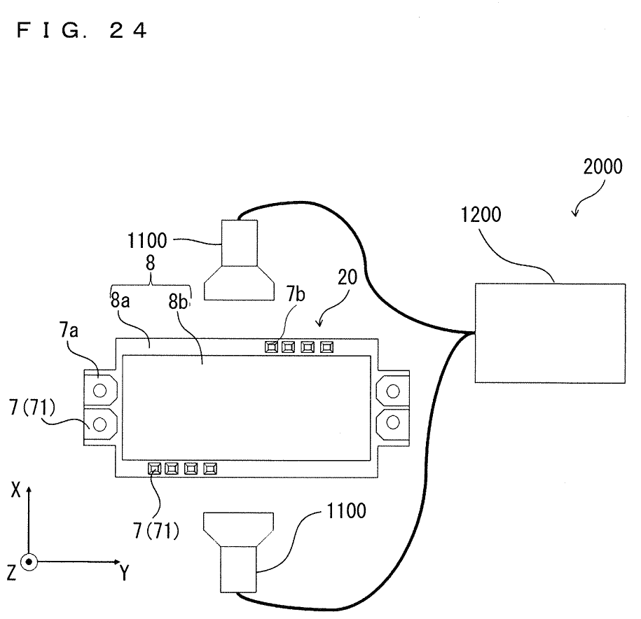

Next, an example configuration of a semiconductor inspection apparatus 2000 that inspects the electrical characteristics of the semiconductor device 20 is described with reference to FIG. 24. FIG. 24 is a schematic top view illustrating an example configuration of the semiconductor inspection apparatus 2000. Note that a configuration diagram illustrating an example configuration of the semiconductor inspection apparatus 2000 would be similar to FIGS. 5, 9, and 11, and therefore, is not shown herein. Also, a flowchart illustrating an operation flow of the semiconductor inspection apparatus 2000 would be similar to FIGS. 8, 10, and 16, and therefore, is not shown herein. Note that, as illustrated in FIGS. 17 and 18, an appearance inspection apparatus 1500 may be included.

In the second preferred embodiment, the identification portions 9 are disposed on side surfaces of the semiconductor device 20, and therefore, the imaging unit 1100 images the semiconductor device 20 from the side surfaces as illustrated in FIG. 24. In the second preferred embodiment, the identification portions 9 are disposed on the side surfaces facing the X-axis direction among the side surfaces of the semiconductor device 20, and therefore, the imaging unit 1100 images the semiconductor device 20 from the positive side of the X-axis direction and the negative side of the X-axis direction, with the semiconductor device 20 interposed therebetween. Note that the imaging unit 1100 of the second preferred embodiment includes two cameras, the imaging range of one camera is a range in which the entire one surface of the side surfaces of the semiconductor device 20 facing in the X-axis direction falls, and the cameras are fixed on the positive side of the X-axis direction and the negative side of the X-axis direction, with the semiconductor device 20 interposed therebetween. Note that, in a case where the imaging range of one camera is a range in which part of one of the side surfaces of the semiconductor device 20 facing in the X-axis direction falls, the cameras may be provided to be movable in the Y-axis direction and the Z-axis direction, for example. Further, in a case where the imaging range of one camera is a range in which part of one of the side surfaces facing in the X-axis direction among the side surfaces of the semiconductor device 20 falls, a plurality of cameras may be provided in a fixed manner.

Note that, in a case where the identification portions 9 are disposed on the surfaces facing in the Y-axis direction among the side surfaces of the semiconductor device 20, the imaging unit 1100 may image the semiconductor device 20 from the Y-axis direction. Further, in a case where the identification portions 9 are disposed on both the surfaces facing in the X-axis direction and the surfaces facing in the Y-axis direction among the side surfaces of the resin portion 8, the imaging unit 1100 may image the semiconductor device 20 from both the X-axis direction and the Y-axis direction.

### Third Preferred Embodiment

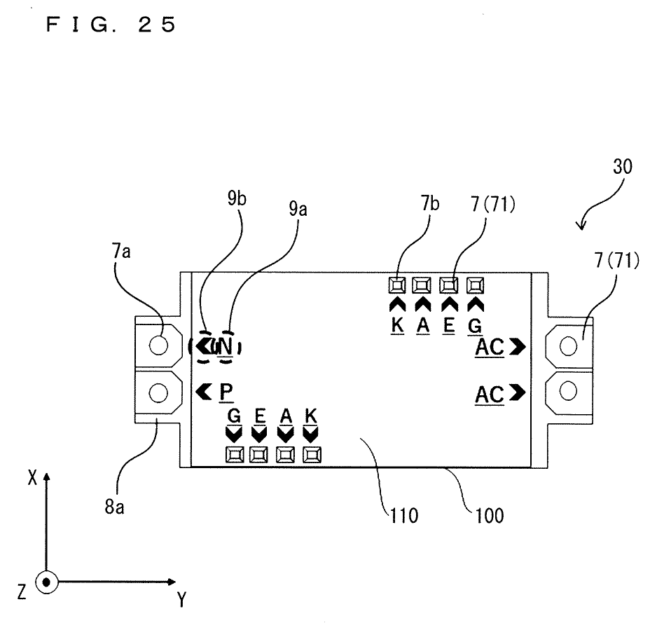

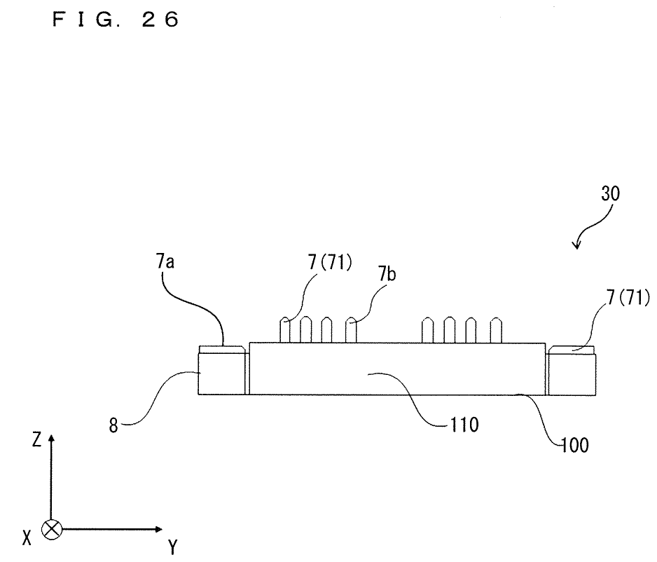

A semiconductor device 30 according to a third preferred embodiment is now described, with reference to FIGS. 25 and 26. FIG. 25 is a schematic top view of the semiconductor device 30 according to the third preferred embodiment. FIG. 26 is a schematic side view of the semiconductor device 30 according to the third preferred embodiment. Note that the dashed lines in FIG. 25 do not indicate identification portions 9.

In the semiconductor device 30 according to the third preferred embodiment, the identification portions 9 are disposed on the surface of a cover 110 of an inspection jig 100. In the semiconductor device 10 according to the first preferred embodiment and the semiconductor device 20 according to the second preferred embodiment, the identification portions 9 are disposed on the surface of the resin portion 8. However, the semiconductor device 30 according to the third preferred embodiment differs in that the identification portions 9 are disposed on the surface of the inspection jig 100. That is, the identification portions 9 are not disposed directly on the semiconductor device 30 of the third preferred embodiment.

The semiconductor device 30 according to the third preferred embodiment is a semiconductor device having a structure in which terminals having different shapes coexist in one package or a structure in which the distances between terminals exposed to outside of the package are not uniform in a portion in the package, and includes a semiconductor element 5, a resin portion 8 provided so as to cover the semiconductor element 5, and a plurality of terminals 7 each of which terminal has one end electrically connected to the semiconductor element 5 and the other end exposed through the surface of the resin portion 8.

The inspection jig 100 is a jig that is used in the above-described inspecting process in the process of manufacturing the semiconductor device 30. The inspection jig 100 includes the cover 110 provided so as to expose the other end of each of the plurality of terminals 7. The cover 110 of the inspection jig 100 of the third preferred embodiment is provided to cover the upper surface of the semiconductor device 30, so as to expose the other end of each of the plurality of terminals 7. The cover 110 of the inspection jig 100 has holes in the surface of the cover 110 at positions corresponding to the other ends of the respective terminals of the plurality of terminals 7. As a result, the other end of each of the plurality of terminals 7 can be exposed through the surface of the cover 110.

The cover 110 includes the identification portions 9 having a function with which the positions of the respective exposed portions 71 of the plurality of terminals 7 can be identified.

Also, the identification portions 9 may further have a function with which the type of each of the plurality of terminals 7 can be identified. Further, the identification portions 9 of the third preferred embodiment are provided on the upper surface of the cover 110, but may be disposed on side surfaces of the cover 110.

Also, the identification portions 9 may be formed with first identification portions 9a having a function with which the type of each of the plurality of terminals 7 can be identified and second identification portions 9b having a function with which any direction can be identified, and one first identification portion 9a and one second identification portion 9b may be provided on the upper surface of the cover 110 for each of the plurality of terminals 7.

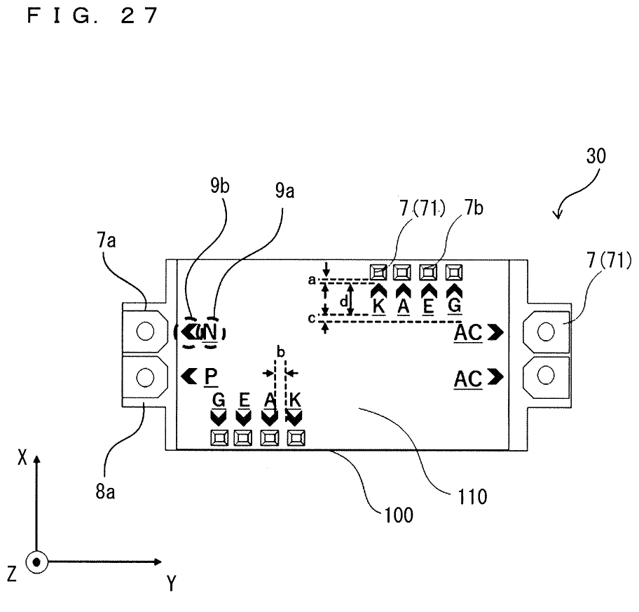

In a case where one identification portion 9 is provided on the upper surface of the cover 110 for each one terminal of the plurality of terminals 7, it is desirable to provide each identification portion 9 so that it will be easy to determine to which terminal 7 the identification portion 9 corresponds. As illustrated in FIG. 27, it is preferable to shorten the distance a between the probe contact position of a terminal 7 and the identification portion 9 corresponding to the terminal 7 to such an extent that it is possible to determine to which terminal 7 each of the identification portions 9 corresponds, and extend the distance b between the identification portions 9 corresponding to the terminals 7 of the same type and the distance c between the identification portions 9 corresponding to the terminals 7 of different types, for example. For example, the distance c is preferably longer than a distance d between the upper end of a first identification portion 9a and the lower end of a second identification portion 9b corresponding to the first identification portion 9a.

Also, the distance a is preferably constant, regardless of the types of the terminals 7.

As illustrated in FIG. 25, the first identification portions 9a may be formed with different characters depending on the types (collector terminal, emitter terminal, gate terminal, and the like) of the plurality of terminals 7. Note that the first identification portions 9a are only required to have a function of identifying the respective types of the plurality of terminals 7, and may be formed with different figures depending on the types of the plurality of terminals 7, or may be formed with different colors depending on the types of the plurality of terminals 7.

As illustrated in FIG. 25, the second identification portions 9b may have a shape from which any direction can be easily identified. As illustrated in FIG. 25, each second identification portion 9b may be formed with an arrow, or may be formed with a triangle, for example. The second identification portions 9b are disposed so as to indicate the positions of the exposed portions 71 of the corresponding terminals 7. As illustrated in FIGS. 25 and 26, the cover 110 of the inspection jig 100 is provided so as to cover the upper surface of the semiconductor device 30, and the second identification portions 9b are located on the inner side of the positions of the exposed portions 71 of the terminals 7. Accordingly, the second identification portions 9b are provided so as to point in the outer peripheral direction of the upper surface of the resin portion 8.

Further, the identification portions 9 may be provided on side surfaces of the cover 110. Also, the identification portions 9 may be formed with the two-dimensional codes described above.

The inspection jig 100 that is used to inspect the semiconductor device 30 of the third preferred embodiment is designed as described above. With the configuration in which the identification portions 9 are disposed on the surface of the cover 110 of the inspection jig 100, the same effects as those of the first and second preferred embodiments can be achieved. Further, since the identification portions 9 are not disposed directly on the surface of the semiconductor device 30, the manufacturing cost of the semiconductor device 30 can be lowered. Furthermore, unlike a semiconductor device 30 that is restricted by the material and the surface state to satisfy the electrical characteristics, the semiconductor device 30 of the present preferred embodiment has the cover 110 not restricted by the material and the surface state. In view of this, the cover 110 with high visibility is selected so that the recognition rate of the identification portions 9 disposed on the surface of the cover 110 can be increased.

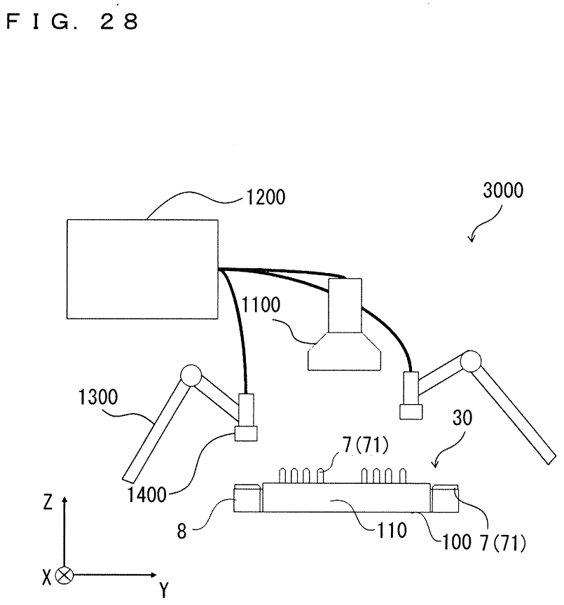

Next, an example configuration of a semiconductor inspection apparatus 3000 that inspects the electrical characteristics of the semiconductor device 30 is described with reference to FIG. 28. FIG. 28 is a schematic side view illustrating an example configuration of the semiconductor inspection apparatus 3000. Note that a configuration diagram illustrating an example configuration of the semiconductor inspection apparatus 3000 would be similar to FIGS. 5, 9, and 11, and therefore, is not shown herein. Also, a flowchart illustrating an operation flow of the semiconductor inspection apparatus 3000 would be similar to FIGS. 8, 10, and 16, and therefore, is not shown herein. Note that, as illustrated in FIGS. 17 and 18, an appearance inspection apparatus 1500 may be included.

In the third preferred embodiment, as the identification portions 9 are disposed on the surface of the cover 110 of the inspection jig 100, the imaging unit 1100 captures an image of the surface of the cover 110 and outputs the captured image, as illustrated in FIG. 28. Note that, in a case where the identification portions 9 are provided on the upper surface of the cover 110, the imaging unit 1100 images the semiconductor device 30 from the upper surface, and, in a case where the identification portions 9 are disposed on side surfaces of the cover 110, the imaging unit 1100 images the semiconductor device 30 from the side surfaces.

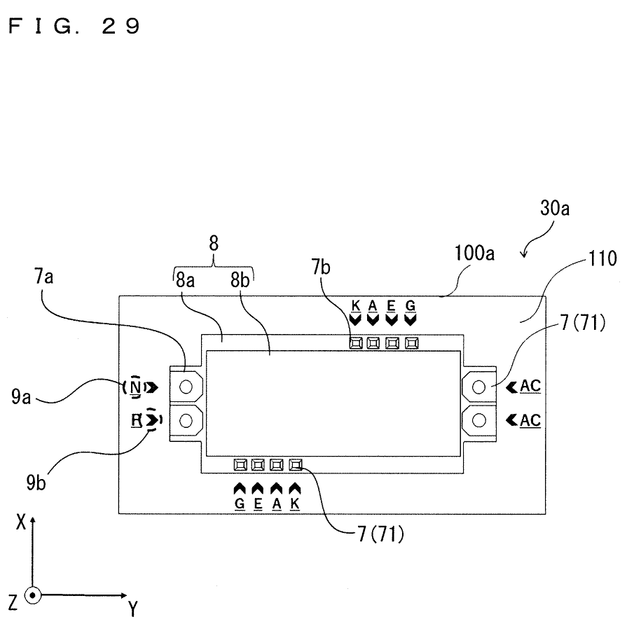

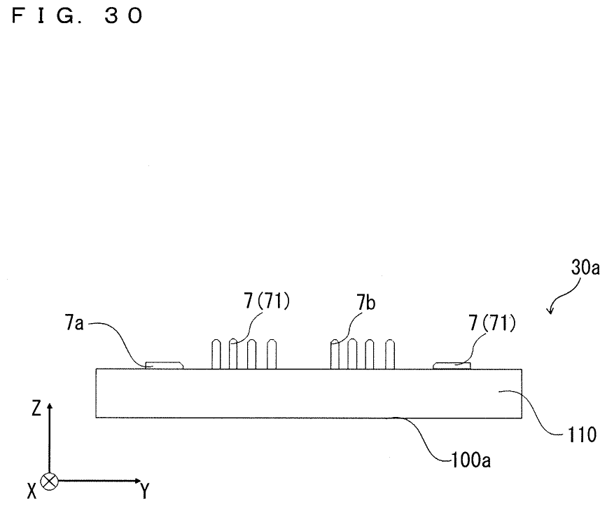

Next, a modification of the third preferred embodiment is described with reference to FIGS. 29 and 30. FIG. 29 is a schematic top view of a semiconductor device 30a according to the modification of the third preferred embodiment. FIG. 30 is a schematic side view of the semiconductor device 30a according to the modification of the third preferred embodiment. Note that the dashed lines in FIG. 29 do not indicate identification portions 9.

An inspection jig 100a that is used for inspecting the semiconductor device 30a according to the modification of the third preferred embodiment differs from the above inspection jig 100 in the shape of the cover 110.

As illustrated in FIGS. 29 and 30, the cover 110 of the inspection jig 100a is provided to surround the outer periphery of the semiconductor device 30a, so as to expose the other end of each of the plurality of terminals 7. The cover 110 may have a recessed portion formed to match the outer shape of the semiconductor device 30a, and surround the outer periphery of the semiconductor device 30a by housing the semiconductor device 30a in the recessed portion. Alternatively, the cover 110 may have a hole formed to match the outer shape of the semiconductor device 30a, and surround the outer periphery of the semiconductor device 30a by housing the semiconductor device 30a in the hole.

Further, as illustrated in FIGS. 29 and 30, the cover 110 of the inspection jig 100a is provided so as to surround the outer periphery of the semiconductor device 30a, and the second identification portions 9b are located on the outer side of the positions of the exposed portions 71 of the terminals 7. Accordingly, the second identification portions 9b are provided so as to point in the central direction of the upper surface of the resin portion 8.

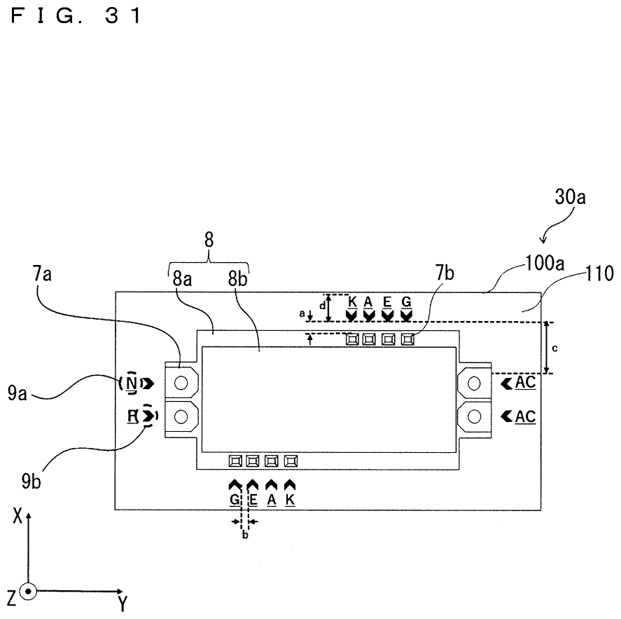

The inspection jig 100a that is used for inspecting the semiconductor device 30a according to the modification of the third preferred embodiment can achieve the same effects as those of the inspection jig 100 described above. Further, in the inspection jig 100a, the identification portions 9 can be disposed on the outer side of the outer periphery of the semiconductor device 30a. Accordingly, the distance c (the distance c in FIG. 31) between the identification portions 9 corresponding to terminals 7 of different types can be extended depending on the shape of the resin portion 8 or the dimension of the surface area of the resin portion 8, as compared with a case where the identification portions 9 are disposed on the inner side of the outer periphery of the semiconductor device 30 as in the inspection jig 100. As a result, the inspection apparatus can easily recognize to which terminal 7 each detected identification portion 9 corresponds, and thus, a probe can be more accurately moved to the position of each terminal 7.

Note that the configurations described in the above preferred embodiments are examples of the contents of the present disclosure, and can be combined with some other known technology. Also, the preferred embodiments can be combined with each other, and the modifications can be combined with each other. Further, some of the configurations can be omitted or modified without departing from the gist of the present disclosure.

In the following, various modes of the present disclosure are collectively described as Appendixes.

### Appendix 1

A semiconductor device that has a structure in which terminals having different shapes coexist in one package or a structure in which distances between terminals exposed to outside of the package are not uniform in a portion in the package, the semiconductor device comprising:
a semiconductor element;
a resin portion that is provided to cover the semiconductor element;
a plurality of terminals each having one end electrically connected to the semiconductor element and another end having an exposed portion exposed through a surface of the resin portion; and
an identification portion that is provided on the surface of the resin portion, and has a function with which a position of the exposed portion of each of the plurality of terminals can be identified.

### Appendix 2

The semiconductor device according to Appendix 1, wherein the semiconductor device has a module structure.

### Appendix 3

The semiconductor device according to Appendix 1 or 2, wherein the identification portion is provided for each of the plurality of terminals on a one-to-one correspondence basis.

### Appendix 4

The semiconductor device according to Appendix 3, wherein the identification portion has a shape from which a direction can be identified.

### Appendix 5

The semiconductor device according to Appendix 4, wherein the identification portion is provided on an upper surface of the resin portion.

### Appendix 6

The semiconductor device according to Appendix 4, wherein the identification portion is provided on a side surface of the resin portion.

### Appendix 7

The semiconductor device according to any one of Appendixes 1 to 3, wherein the identification portion includes a two-dimensional code containing identification information from which a position of the exposed portion of each of the plurality of terminals can be identified.

### Appendix 8

The semiconductor device according to Appendix 1 or 2, wherein the identification portion further has a function with which a type of each of the plurality of terminals can be identified.

### Appendix 9

The semiconductor device according to Appendix 1 or 2, wherein the identification portion includes:
a first identification portion having a shape from which a type of each of the plurality of terminals can be identified; and
a second identification portion having a shape from which a direction can be identified, and
the first identification portion and the second identification portion are provided on a surface of the resin portion for each of the plurality of terminals on a one-to-one correspondence basis.

### Appendix 10

A method of manufacturing a semiconductor device having a structure in which terminals having different shapes coexist in one package or a structure in which distances between terminals exposed to outside of the package are not uniform in a portion in the package, the method comprising:
a connecting process of electrically connecting one end of each of a plurality of terminals to a semiconductor element;
a resin portion forming process of forming a resin portion covering the semiconductor element and part of the plurality of terminals to expose another end of each of the plurality of terminals through a surface of the resin portion; and
an identification portion forming process of forming an identification portion on the surface of the resin portion, the identification portion having a function with which a position of an exposed portion at which the other end of each of the plurality of terminals is exposed through the surface of the resin portion.

### Appendix 11

The method according to Appendix 10, wherein the semiconductor device has a module structure.

### Appendix 12

A semiconductor inspection apparatus that inspects electrical characteristics of the semiconductor device according to any one of Appendixes 1 to 9, the semiconductor inspection apparatus comprising:
an imaging unit that captures an image of the surface of the resin portion and outputs the captured image;
an image acquiring unit that acquires the captured image output from the imaging unit;
a position determining unit that detects the identification portion from the captured image acquired by the image acquiring unit, and determines, from the identification portion, a contact position at which a probe is brought into contact with the exposed portion of the terminal;
an output unit that outputs the contact position determined by the position determining unit; and
a conveyance unit that moves the probe to the contact position, on the basis of the contact position output from the output unit.

### Appendix 13

A semiconductor device inspection jig that is used to inspect electrical characteristics of a semiconductor device having a structure in which terminals having different shapes coexist in one package or a structure in which distances between terminals exposed to outside of the package are not uniform in a portion in the package, the semiconductor device including a semiconductor element, a resin portion provided to cover the semiconductor element, and a plurality of terminals each of which has one end electrically connected to the semiconductor element and another end having an exposed portion exposed through a surface of the resin portion, the semiconductor device inspection jig comprising
a cover that is designed to expose the other end of each of the plurality of terminals, wherein
the cover includes an identification portion having a function with which a position of the exposed portion of each of the plurality of terminals can be identified.

### Appendix 14

The semiconductor device inspection jig according to Appendix 13, wherein the semiconductor device has a module structure.

### Appendix 15

A semiconductor inspection apparatus that inspects electrical characteristics of a semiconductor device using the semiconductor device inspection jig according to Appendix 13 or 14, the semiconductor inspection apparatus comprising:
an imaging unit that captures an image of a surface of the cover and outputs the captured image;
an image acquiring unit that acquires the captured image output from the imaging unit;
a position determining unit that detects the identification portion from the captured image acquired by the image acquiring unit, and determines, from the identification portion, a contact position at which a probe is brought into contact with the exposed portion of the terminal;
an output unit that outputs the contact position determined by the position determining unit; and
a conveyance unit that moves the probe to the contact position, on the basis of the contact position output from the output unit.

While the disclosure has been shown and described in detail, the foregoing description is in all aspects illustrative and not restrictive. It is therefore understood that numerous modifications and variations can be devised.

What is claimed is:

1. A semiconductor device that has a structure in which terminals having different shapes coexist in one package or a structure in which distances between terminals exposed to outside of the package are not uniform in a portion in the package, the semiconductor device comprising:
a semiconductor element;
a resin portion that is provided to cover the semiconductor element;
a plurality of terminals each having one end electrically connected to the semiconductor element and another end having an exposed portion exposed through a surface of the resin portion; and
an identification portion that is provided on the surface of the resin portion, and has a function with which a position of the exposed portion of each of the plurality of terminals can be identified.

2. The semiconductor device according to claim 1, wherein the semiconductor device has a module structure.

3. The semiconductor device according to claim 1, wherein the identification portion is provided for each of the plurality of terminals on a one-to-one correspondence basis.

4. The semiconductor device according to claim 3, wherein the identification portion has a shape from which a direction can be identified.

5. The semiconductor device according to claim 4, wherein the identification portion is provided on an upper surface of the resin portion.

6. The semiconductor device according to claim 4, wherein the identification portion is provided on a side surface of the resin portion.

7. The semiconductor device according to claim 1, wherein the identification portion includes a two-dimensional code containing identification information from which a position of the exposed portion of each of the plurality of terminals can be identified.

8. The semiconductor device according to claim 1, wherein the identification portion further has a function with which a type of each of the plurality of terminals can be identified.

9. The semiconductor device according to claim 1, wherein
the identification portion includes:
a first identification portion having a shape from which a type of each of the plurality of terminals can be identified; and
a second identification portion having a shape from which a direction can be identified, and
the first identification portion and the second identification portion are provided on a surface of the resin portion for each of the plurality of terminals on a one-to-one correspondence basis.

10. A method of manufacturing a semiconductor device having a structure in which terminals having different shapes coexist in one package or a structure in which distances between terminals exposed to outside of the package are not uniform in a portion in the package, the method comprising:
a connecting process of electrically connecting one end of each of a plurality of terminals to a semiconductor element;
a resin portion forming process of forming a resin portion covering the semiconductor element and part of the plurality of terminals to expose another end of each of the plurality of terminals through a surface of the resin portion; and
an identification portion forming process of forming an identification portion on the surface of the resin portion, the identification portion having a function with which a position of an exposed portion at which the other end of each of the plurality of terminals is exposed through the surface of the resin portion.

11. The method of manufacturing a semiconductor device according to claim 10, wherein the semiconductor device has a module structure.

12. A semiconductor inspection apparatus that inspects electrical characteristics of the semiconductor device according to claim 1, the semiconductor inspection apparatus comprising:
an imaging unit that captures an image of the surface of the resin portion and outputs the captured image;
an image acquiring unit that acquires the captured image output from the imaging unit;
a position determining unit that detects the identification portion from the captured image acquired by the image acquiring unit, and determines, from the identification portion, a contact position at which a probe is brought into contact with the exposed portion of the terminal;
an output unit that outputs the contact position determined by the position determining unit; and
a conveyance unit that moves the probe to the contact position, on the basis of the contact position output from the output unit.

13. A semiconductor device inspection jig that is used to inspect electrical characteristics of a semiconductor device having a structure in which terminals having different shapes coexist in one package or a structure in which distances between terminals exposed to outside of the package are not uniform in a portion in the package, the semiconductor device including a semiconductor element, a resin portion provided to cover the semiconductor element, and a plurality of terminals each of which has one end electrically connected to the semiconductor element and another end having an exposed portion exposed through a surface of the resin portion, the semiconductor device inspection jig comprising
a cover that is designed to expose the other end of each of the plurality of terminals, wherein
the cover includes an identification portion having a function with which a position of the exposed portion of each of the plurality of terminals can be identified.

14. The semiconductor device inspection jig according to claim 13, wherein the semiconductor device has a module structure.

15. A semiconductor inspection apparatus that inspects electrical characteristics of a semiconductor device using the semiconductor device inspection jig according to claim 13, the semiconductor inspection apparatus comprising:
an imaging unit that captures an image of a surface of the cover and outputs the captured image;
an image acquiring unit that acquires the captured image output from the imaging unit;
a position determining unit that detects the identification portion from the captured image acquired by the image acquiring unit, and determines, from the identification portion, a contact position at which a probe is brought into contact with the exposed portion of the terminal;
an output unit that outputs the contact position determined by the position determining unit; and
a conveyance unit that moves the probe to the contact position, on the basis of the contact position output from the output unit.
